(19) United States
(12) Patent Application Publication
(10) Pub. No.: US 2026/0278187 A1
(43) Pub. Date: Sep. 17, 2026

(54) DETERMINING CAMERA PLACEMENT FOR OPTIMIZED SCENE COVERAGE USING LIGHT TRANSPORT SIMULATION

(71) Applicant: Nvidia Corporation, Santa Clara, CA (US)

(72) Inventors: Shenxin Jiang, Santa Clara, CA (US); Yuxing Wang, Burlingame, CA (US); Shangru Li, Philadelphia, PA (US); Haoquan Liang, San Jose, CA (US); Tongwei Dai, Los Altos, CA (US); Zheng Tang, Bothell, WA (US)

(21) Appl. No.: 19/080,481

(22) Filed: Mar. 14, 2025

(51) Int. Cl. G06F 30/13; G06T 15/06

(52) U.S. Cl. CPC G06F 30/13; G06T 15/06; G06T 2210/21

(57) ABSTRACT

Approaches are described for determining camera placement within an environment using a grid-based spatial representation. A grid model is generated to define accessible and inaccessible regions, with connectivity values computed for each grid cell based on the number of unobstructed sightlines in predefined directions. One or more focus points are identified within the grid model based on connectivity analysis to serve as target regions for coverage optimization. A candidate set of camera placement locations is determined by evaluating spatial constraints, occlusion conditions, and predefined placement parameters. A raycasting process is applied to validate camera positions to ensure an unobstructed view of the focus point. Once a camera is placed, its field of view is computed, and an accessibility update is performed to refine placement decisions iteratively. This process continues until all designated areas meet predefined coverage criteria, optimizing scene visibility while minimizing redundant placements and computational overhead.

### BACKGROUND

Effective camera placement is essential in applications such as surveillance, robotics, computer vision, and virtual simulations. The positioning of cameras may influence scene coverage, object detection, tracking, and three-dimensional reconstruction. The placement of cameras in an environment may affect the ability to capture visual information for these applications. Suboptimal placement of cameras may result in blind spots, obstructions, and inefficient coverage, which makes it difficult to track objects, reconstruct scenes, or analyze spatial relationships. Gaps in coverage may require additional cameras or processing to compensate, which may increase hardware costs and computational demands. As camera-based technologies are used in more complex environments, careful consideration of placement is important for improving accuracy, efficiency, and overall system performance.

### BRIEF DESCRIPTION OF THE DRAWINGS

Various embodiments in accordance with the present disclosure will be described with reference to the drawings, in which:

FIG. 1A illustrates one example approach to camera placement within an environment containing obstacles or structures, according to at least one embodiment;

FIG. 1B illustrates another example approach to camera placement within an environment containing obstacles or structures, according to at least one embodiment;

FIGS. 2A and 2B illustrate an example process for constructing a grid-based model of an environment and determining accessibility, according to at least one embodiment;

FIG. 3A illustrates an example grid-based representation of an environment with connectivity information, according to at least one embodiment;

FIG. 3B illustrates an example numerical representation of the connectivity values assigned to each grid cell, according to at least one embodiment;

FIG. 3C illustrates an example of connectivity values in four principal directions within an environment, according to at least one embodiment;

FIG. 4A illustrates an example process flow with illustrations for determining camera placement, according to at least one embodiment;

FIG. 4B illustrates an example flow chart for determining camera placement, according to at least one embodiment;

FIG. 4C illustrates an example flow chart for determining camera placement using a distance field-based approach, according to at least one embodiment;

FIG. 5 illustrates a flowchart depicting an example process for optimizing solder paste overprint areas, according to at least one embodiment;

FIG. 6 illustrates an example system, including a hardware design optimization system, according to at least one embodiment;

FIG. 7A illustrates inference and/or training logic, according to at least one embodiment;

FIG. 7B illustrates inference and/or training logic, according to at least one embodiment;

FIG. 8 illustrates an example data center system, according to at least one embodiment;

FIG. 9 illustrates a computer system, according to at least one embodiment;

FIG. 10 illustrates a computer system, according to at least one embodiment;

FIG. 11 illustrates at least portions of a graphics processor, according to one or more embodiments;

FIG. 12 illustrates at least portions of a graphics processor, according to one or more embodiments;

FIG. 13 is an example data flow diagram for an advanced computing pipeline, in accordance with at least one embodiment;

FIG. 14 is a system diagram for an example system for training, adapting, instantiating and deploying machine learning models in an advanced computing pipeline, in accordance with at least one embodiment; and

FIGS. 15A and 15B illustrate a data flow diagram for a process to train a machine learning model, as well as client-server architecture to enhance annotation tools with pre-trained annotation models, in accordance with at least one embodiment.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

The systems and methods described herein may be used by, without limitation, non-autonomous vehicles or machines, semi-autonomous or autonomous vehicles or machines (e.g., in one or more advanced driver assistance systems (ADAS), one or more in-vehicle infotainment systems, one or more emergency vehicle detection systems), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, trains, underwater craft, remotely operated vehicles such as drones, and/or other vehicle types. Further, the systems and methods described herein may be used for a variety of purposes, by way of example and without limitation, for machine control, machine locomotion, machine driving, synthetic data generation, generative AI, model training or updating, perception, augmented reality, virtual reality, mixed reality, robotics, security and surveillance, simulation and digital twinning, autonomous or semi-autonomous machine applications, deep learning, environment simulation, data center processing, conversational AI, light transport simulation (e.g., ray-tracing, path tracing, etc.), collaborative content creation for 3D assets, generative AI, cloud computing, and/or any other suitable applications.

Disclosed embodiments may be comprised in a variety of different systems such as automotive systems (e.g., an in-vehicle infotainment system for an autonomous or semi-autonomous machine, a perception system for an autonomous or semi-autonomous machine), systems implemented using a robot, aerial systems, medical systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems implementing one or more language models—such as large language models (LLMs), vision language models (VLMs), multi-modal language models, etc., systems for performing generative AI operations (e.g., using one or more language models, transformer models, etc.), systems for performing light transport simulation, systems for performing collaborative content creation for 3D assets, systems implemented at least partially using cloud computing resources, and/or other types of systems.

Approaches in accordance with various embodiments can be used to generate one or more parameters for a content generation environment. In at least one embodiment, a trained machine learning (ML) and/or artificial intelligence (AI) system, such as a large language model (LLM) or a vision language model (VLM), may be used to generate parameters for the content generation environment, such as, but not limited to, camera settings, scene lighting, video parameters, and/or the like, used for displaying objects within a scene. The parameters may be based on an input provided by a user or a proxy for a user to a trained language model (e.g., LLM, VLM, etc.) that can then generate one or more settings in accordance with the input. Various embodiments may be used to generate settings in two-dimensional (2D) or three-dimensional (3D) settings. For embodiments that incorporate one or more language models—that is, one or more LLMs, one or more VLMs, or a combination of LLMs and VLMs, the language model(s) may receive an input (e.g., a prompt, a request, a query, etc.) that is parsed or otherwise formatted to generate a deterministic output. For example, the input provided to the language model may include a particular format for the output results, an example of desired output results, a particular list of parameters and their respective formatting, and the like. An input generator (e.g., a prompt generator), which may be driven or otherwise guided by one or more AI and/or ML systems, may be used to generate this input based on an initial input received from a user, a device, a proxy, and/or the like. A modified input generated by the input generator may then be provided to the language model, which will generate an output set of parameters. This output may be further evaluated with a reviewer, or other system, to ensure that the output is appropriate. Thereafter, a configuration file may be generated and/or the parameters may be directly provided to an environment to configure different components (e.g., camera settings, lighting, etc.) based on the parameters generated by the language model.

In some examples, the machine learning model(s) (e.g., deep neural networks, language models, LLMs, VLMs, multi-modal language models, perception models, tracking models, fusion models, transformer models, diffusion models, encoder-only models, decoder-only models, encoder-decoder models, neural rendering field (NERF) models, etc.) described herein may be packaged as a microservice—such an inference microservice (e.g., NVIDIA NIMs)—which may include a container (e.g., an operating system (OS)-level virtualization package) that may include an application programming interface (API) layer, a server layer, a runtime layer, and/or at least one model “engine.” For example, the inference microservice may include the container itself and the model(s) (e.g., weights and biases). In some instances, such as where the machine learning model(s) is small enough (e.g., has a small enough number of parameters), the model(s) may be included within the container itself. In other examples—such as where the model(s) is large—the model(s) may be hosted/stored in the cloud (e.g., in a data center) and/or may be hosted on-premises and/or at the edge (e.g., on a local server or computing device, but outside of the container). In such embodiments, the model(s) may be accessible via one or more APIs-such as REST APIs. As such, and in some embodiments, the machine learning model(s) described herein may be deployed as an inference microservice to accelerate deployment of a model(s) on any cloud, data center, or edge computing system, while ensuring the data is secure. For example, the inference microservice may include one or more APIs, a pre-configured container for simplified deployment, an optimized inference engine (e.g., built using a standardized AI model deployment an execution software, such as NVIDIA's Triton Inference Server, and/or one or more APIs for high performance deep learning inference, which may include an inference runtime and model optimizations that deliver low latency and high throughput for production applications—such as NVIDIA's TensorRT), and/or enterprise management data for telemetry (e.g., including identity, metrics, health checks, and/or monitoring).

The machine learning model(s) described herein may be included as part of the microservice along with an accelerated infrastructure with the ability to deploy with a single command and/or orchestrate and auto-scale with a container orchestration system on accelerated infrastructure (e.g., on a single device up to data center scale). As such, the inference microservice may include the machine learning model(s) (e.g., that has been optimized for high performance inference), an inference runtime software to execute the machine learning model(s) and provide outputs/responses to inputs (e.g., user queries, prompts, etc.), and enterprise management software to provide health checks, identity, and/or other monitoring. In some embodiments, the inference microservice may include software to perform in-place replacement and/or updating to the machine learning model(s). When replacing or updating, the software that performs the replacement/updating may maintain user configurations of the inference runtime software and enterprise management software.

Approaches in accordance with embodiments of the present disclosure address challenges associated with optimal camera placement for maximizing scene coverage while minimizing occlusions and redundant placements. Disclosed embodiments may utilize spatial analysis techniques, including a structured grid representation of an environment, raycasting for visibility evaluation, and connectivity-based metrics to identify suitable camera locations. In embodiments of the present disclosure, a scene may be represented as a two-dimensional (2D) grid mapped onto a three-dimensional (3D) space. This mapping may be based on a grid-based representation of areas in an environment. Such a grid-based representation may be used to define an accessible grid, where each grid cell may be classified as accessible or inaccessible based on whether it corresponds to a navigable area. This grid representation may serve as the foundation for further camera placement optimization.

A connectivity grid may be generated to quantify the spatial relationships between grid points in different directions. The connectivity grid may be computed for four principal orientations: x-positive, x-negative, y-positive, and y-negative. Each grid cell may be assigned a value indicating how many consecutive cells in a given direction remain unobstructed. Higher values may correspond to regions where a camera may have a wider, less obstructed view. By analyzing connectivity values across multiple directions, it may be determined which locations may provide the most effective coverage.

Based on the accessibility and connectivity information, a focus point selection process may be conducted to identify candidate locations for camera placement. A focus point may be defined as a position in the scene that is both accessible and has a high connectivity value, meaning that placing a camera at that point may result in broad coverage. If multiple candidate points exhibit similar connectivity values, additional selection criteria may be applied, such as prioritizing positions near scene boundaries or corners, where cameras may provide wider fields of view. Once a focus point is selected, raycasting operations may be performed to determine valid camera placement positions. Raycasting may involve projecting rays from the focus point in various directions to detect obstacles and measure distances. A camera may be placed at a location where it may maintain an unobstructed view of the focus point while adhering to predefined constraints such as minimum and maximum camera-to-object distances, camera height limitations, and downward viewing angles. The use of raycasting may allow for precise validation of potential placements while ensuring that cameras do not intersect with scene geometry.

After a camera is placed, an evaluation process may be performed to determine which regions of the scene are now covered. This may involve computing the camera frustum, which is the three-dimensional volume representing the camera's field of view. The intersection of the frustum with the ground plane may be calculated to identify which grid cells are visible from the camera's position. A back-projection method may be used to verify coverage by tracing rays from the covered grid cells back to the camera, ensuring that they are not occluded by obstacles.

Embodiments in accordance with the present disclosure may iteratively refine the camera placement by updating connectivity values to reflect newly covered areas. When a camera is placed, the connectivity values of the covered grid cells may be adjusted to prevent redundant placements. This update process may ensure that subsequent cameras are positioned in regions that maximize additional coverage rather than overlapping with existing cameras. In certain embodiments, additional constraints may be applied to fine-tune camera placement. Users may define parameters such as camera rotation constraints, coverage density thresholds, and scene-specific occlusion handling. By incorporating these constraints, such systems and methods may effectively adapt to various real-world conditions, including dynamic environments where object movement or environmental changes may affect visibility.

Embodiments in accordance with the present disclosure may provide several technical advantages. For example, one technical advantage lies in the deterministic and computationally efficient approach to camera placement, which may address the instability and high computational costs of traditional optimization techniques such as genetic algorithms. Genetic algorithm-based solutions may require extensive fine-tuning of hyperparameters, involve a probabilistic search process, and often fail to guarantee consistent results. These methods may conduct numerous iterations to converge on an optimal placement, and may lead to unpredictable performance and excessive computational overhead, particularly in complex or large-scale environments. In contrast, disclosed approaches may employ a connectivity-based evaluation mechanism that prioritizes placement locations based on spatial connectivity to ensure optimal coverage with minimal computational redundancy. By leveraging a structured 2D scene representation combined with directional connectivity metrics, the disclosed approach may eliminate the need for iterative trial-and-error processing, resulting in a stable, repeatable, and computationally efficient method for determining camera positions.

Another technical advantage may be the hybrid 2D-3D spatial representation, which simplifies computational complexity while maintaining high placement accuracy. Fully 3D-based optimization approaches may introduce significant computational challenges, as they must evaluate camera positions, orientations, and visibility across a vast continuous space, which may result in a combinatorial explosion in potential solutions. Traditional 3D methods may require exhaustive searches, ray-marching techniques, or heuristic approximations to estimate camera effectiveness. In contrast, disclosed approaches may transform the problem into a 2D spatial abstraction by constructing an accessible grid using a navigation mesh. The navigation mesh may define navigable areas in the environment such that the placement process operates on a structured, discretized representation rather than an unbounded 3D space. The disclosed embodiments may then selectively apply 3D raycasting techniques to validate visibility and ensure that cameras maintain an unobstructed view of their target regions. This combination of 2D abstraction for placement decisions and 3D validation for accuracy may significantly reduce computational overhead while retaining the precision necessary for effective scene coverage.

A further technical advantage may be the reduction in degrees of freedom (DoF) for camera placement which leads to a more efficient optimization process with improved scalability. Many existing solutions may attempt to optimize all camera parameters simultaneously, including position, rotation, field of view, and focal depth. These methods may struggle with the exponential growth in complexity when optimizing across multiple variables, often requiring advanced optimization heuristics that may still result in suboptimal configurations. Disclosed approaches may decompose the placement problem by first determining a high-connectivity focus point and then deriving the optimal camera orientation based on this selection. Instead of evaluating arbitrary rotations, disclosed embodiments may classify camera orientations into four primary yaw rotation categories: x-positive, x-negative, y-positive, and y-negative, each corresponding to a constrained search space that aligns with the structured placement methodology. By reducing the DoF and constraining orientation selection to a focus-point-based rotation determination, the disclosed approach may streamline the optimization process, resulting in faster computation and more predictable placement accuracy.

Additionally, another technical advantage may be the automated and scalable nature of the camera placement process, which enhances adaptability in dynamic and large-scale environments. Manual camera placement approaches may require extensive human intervention, which makes them impractical for environments with frequent scene modifications, such as industrial automation, robotic perception, or security monitoring. Heuristic-based placement strategies may also suffer from rigid predefined rules that fail to adapt to varying spatial constraints. Disclosed approaches may employ an iterative refinement mechanism, wherein each camera placement is followed by an update to the connectivity grid, dynamically recalculating scene coverage such that subsequent placements maximize additional visibility rather than overlapping with existing coverage. This real-time adaptive placement process may allow for flexible deployment across different environments without requiring predefined heuristics or manual adjustments.

Variations of this and other such functionality can be used as well within the scope of the various embodiments as would be apparent to one of ordinary skill in the art in light of the teachings and suggestions contained herein.

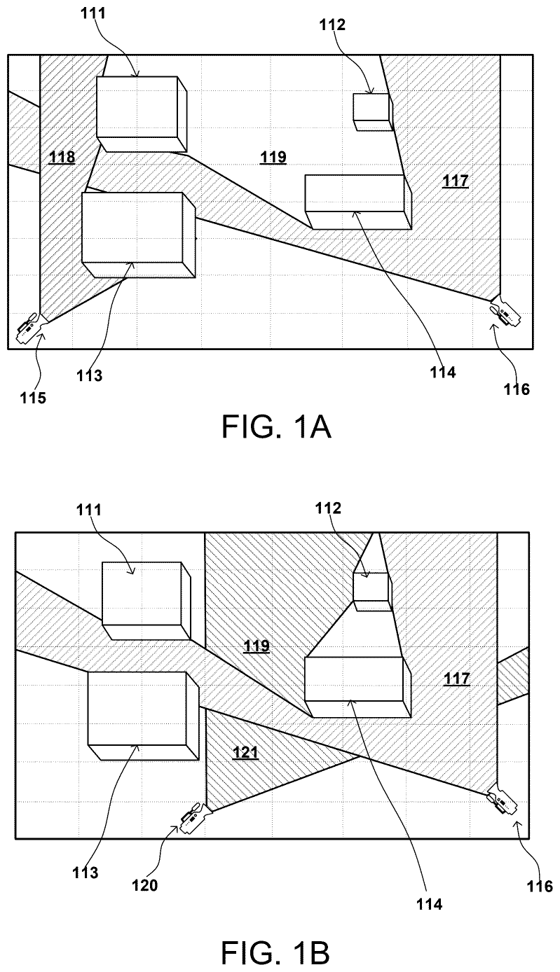

FIGS. 1A and 1B illustrate two example approaches to camera placement within an environment containing obstacles or structures. Such an environment may include multiple objects representing buildings, walls, or other obstructions that restrict the field of view of cameras placed within the scene. FIG. 1A depicts a placement strategy where cameras 115 and 116 are positioned at two diagonal corners of the environment. In this configuration, each camera's field of view (FoV) defines the region it can observe. Camera 115 has a coverage area labeled 118, while camera 116 has a coverage area labeled 117. These coverage regions extend outward from each camera's position and are determined by factors such as lens characteristics, mounting height, and orientation. The shape and extent of these regions are influenced by the optical properties and range of the cameras, meaning that obstacles within the environment may obstruct visibility, casting occlusion shadows and creating blind spots.

The placement strategy illustrated in FIG. 1A may result in a blind spot 119, an area within the environment that is not covered by either of the two cameras. This occurs because the FoV regions of cameras 115 and 116 do not sufficiently overlap or extend into that portion of the scene. In real-world applications, blind spots like 119 may arise when cameras are positioned without an analysis of occlusions or without consideration of how their fields of view interact. For example, if an object or an individual moves into blind spot 119, neither camera 115 nor camera 116 would be able to detect it. Such limitations pose significant challenges in applications that require comprehensive scene monitoring, such as security surveillance, autonomous navigation, robotic perception, and industrial inspection systems.

One possible solution to mitigate this issue may be to install an additional camera to cover the blind spot. However, this approach increases both hardware costs and system complexity, making it an inefficient solution. Instead, optimizing camera placement through computational methods, such as connectivity-based analysis or distance field refinement, may provide a more effective approach to maximizing coverage while minimizing redundant camera deployments.

FIG. 1B illustrates an alternative camera placement approach in which cameras are positioned based on spatial analysis in accordance with the present disclosure. Unlike the placement strategy shown in FIG. 1A, the placement of camera 120 may be determined through an evaluative process that considers existing coverage gaps, occlusion constraints, and connectivity properties of the environment. The introduction of camera 120 extends coverage into previously unmonitored regions, with coverage area 121 specifically targeting blind spot 119, which remained outside the fields of view of cameras 115 and 116 in FIG. 1A. By positioning camera 120 in this computed location, visibility into the previously unmonitored area is established without excessive redundancy in overlapping coverage. The position of camera 120 may be selected through a step-by-step analysis that begins with an evaluation of the visibility range of the existing cameras 115 and 116. The placement of camera 120 is conducted through an iterative process in which the environment is assessed for regions requiring additional monitoring.

A first step in such a process may be analyzing the connectivity properties of the environment, determining how regions of the scene are linked based on accessibility and obstructions. Once blind spot 119 is identified as an uncovered area, the spatial positioning of camera 120 is calculated to ensure that the camera's field of view extends into this region while avoiding unnecessary overlap with existing coverage areas. The placement process may also consider additional field-of-view constraints such that the camera is neither too close nor too far from its focus area, maintaining an optimal balance between resolution and coverage width. The placement of camera 120 may also account for occlusion effects introduced by structures 111-114. Since these structures obstruct visibility, their spatial relationships with the target region must be considered when determining the optimal angle and height for the camera. A raycasting technique may be employed to verify that camera 120 maintains a clear line of sight to blind spot 119 without being obstructed by objects in the scene. The final validation of the placement of camera 120 may be performed by simulating the camera's frustum, which represents the three-dimensional volume of space visible to the camera. The frustum is projected onto the environment to determine whether all points within coverage area 121 fall within the optical range of camera 120. If any regions remain outside the frustum, adjustments to the placement position or camera orientation may be made. Additionally, predefined placement constraints such as minimum and maximum allowable distances, downward viewing angles, and rotation constraints are considered to ensure that the placement aligns with technical requirements.

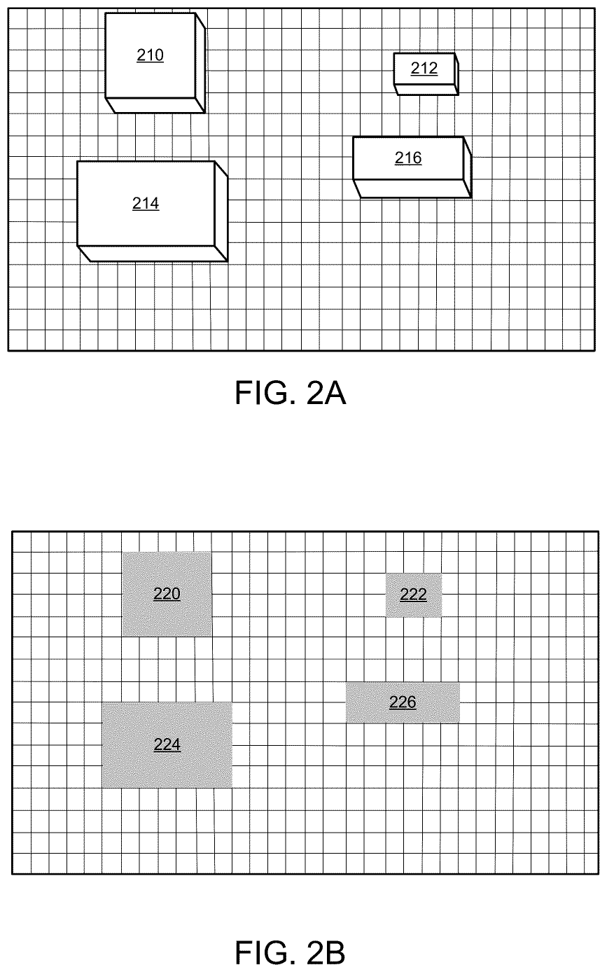

FIGS. 2A and 2B illustrate an example process for constructing a grid-based model of an environment and determining accessibility within that model. FIG. 2A depicts an example environment containing structures 210, 212, 214, and 216. The environment is subdivided into discrete grid cells, each representing a defined spatial resolution. The grid structure may serve as the basis for accessibility analysis, in which each cell is evaluated to determine whether it is accessible or obstructed by environmental elements such as structures 210, 212, 214, and 216. The grid resolution is selected based on the desired level of spatial granularity, with smaller grid cells allowing for more precise representation of accessibility constraints and larger grid cells providing a more computationally efficient but coarser representation. The accessibility of each grid cell may be determined by referencing a navigation mesh (NavMesh) or other spatial representation of the environment. Cells that correspond to navigable or unoccupied areas are marked as accessible, while cells that coincide with structures 210, 212, 214, and 216 are marked as inaccessible. This marking process allows the system to construct a binary representation of the environment, where accessible cells are assigned one value and inaccessible cells are assigned another. The accessibility map generated through this process may be used as a foundational dataset for subsequent camera placement and scene coverage evaluations.

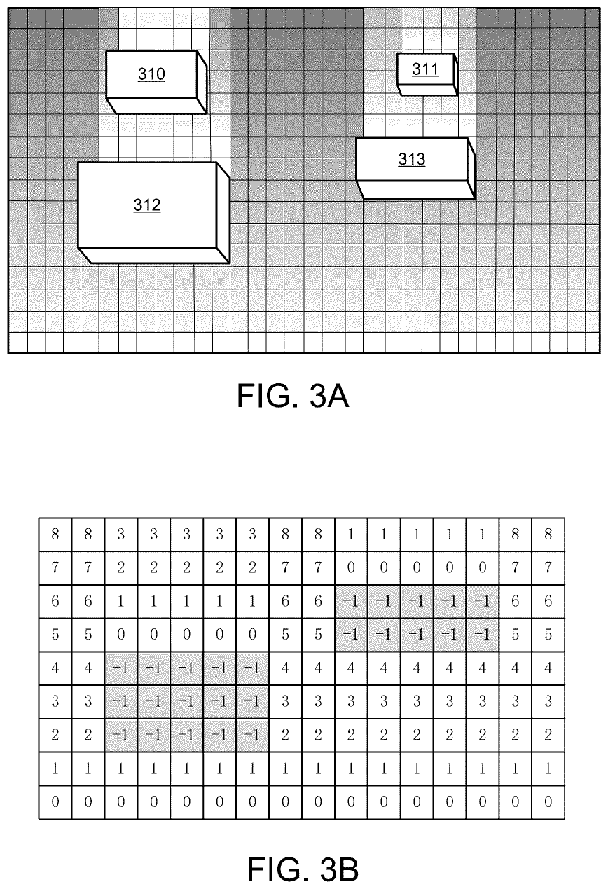

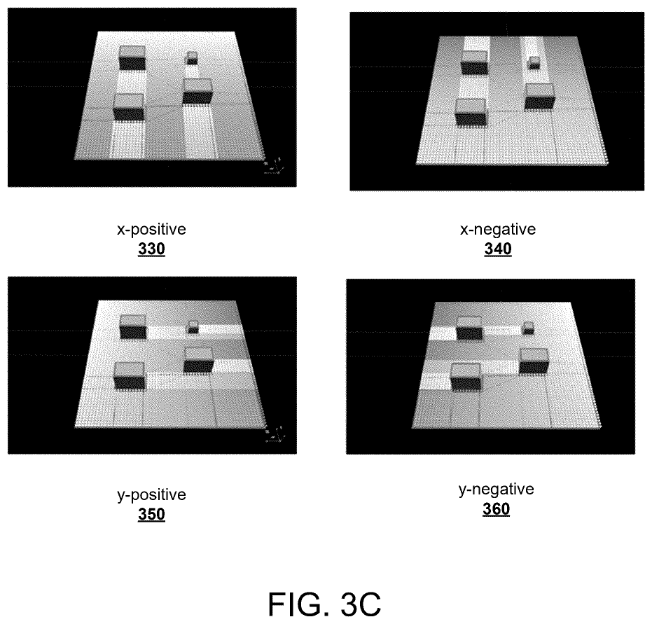

FIG. 2B illustrates an example accessibility determination process, in accordance with one embodiment. For example, as illustrated in FIG. 2B, regions 220, 222, 224, and 226 are designated as inaccessible due to their alignment with obstacles in the environment. The inaccessible regions correspond to the spatial footprint of structures present in FIG. 2A, with grid cells overlapping these structures being recorded as obstructed. The accessibility information may be stored in a structured format, such as a matrix or occupancy grid for efficient querying and computational analysis. This accessibility map may serve as an input for subsequent connectivity determination, in which the relationship between accessible regions is analyzed to identify pathways, occlusion-free zones, and potential camera placement locations. In one embodiment, the structured grid representation shown in FIGS. 2A and 2B provides a basis for evaluating spatial connectivity by establishing a systematic framework for identifying how different regions of the environment are linked. Connectivity analysis is discussed in further detail in accordance with FIGS. 3A-3B.

FIG. 3A illustrates an example evaluation of connectivity within an environment containing structures 310, 311, 312, and 313. These structures may represent obstacles that block visibility and limit accessibility within the grid-based spatial representation. The connectivity of each region is assessed to determine how well different parts of the environment are linked based on the extent of unobstructed space available in predefined directions. Connectivity in this context may refer to the number of consecutive accessible grid cells extending outward from a given cell before encountering an obstacle such as a structure or the boundary of the environment. Such a connectivity evaluation may be performed in four principal directions: x-positive, x-negative, y-positive, and y-negative, which are further illustrated in detail in accordance with FIG. 3C. Each accessible cell may be assigned a connectivity value that quantifies the number of connected open cells in each of these four directions. For example, if a cell in the grid has an unobstructed path extending five cells to the right before reaching a structure, its connectivity value in the y-positive direction would be 5. Similarly, if another cell is surrounded by obstacles on multiple sides, its connectivity values would be lower because it has fewer available paths leading to open space. The process of determining connectivity values may start at each accessible grid cell and iteratively counts the number of consecutive accessible cells extending outward in each of the four principal directions. When an obstacle is encountered, the count terminates, and the connectivity value for that direction is recorded. This computation is performed for every accessible cell in the environment, resulting in a connectivity map that highlights regions where longer unobstructed paths exist and where movement or visibility is restricted.

The shading in FIG. 3A may represent the computed connectivity values, with darker regions corresponding to areas where cells maintain a longer unobstructed path in multiple directions. These darker areas indicate locations with high connectivity, meaning they provide broader spatial access and better visibility. Lighter areas appear near obstacles, where connectivity is lower due to obstructions limiting the number of accessible cells in one or more directions. For example, a grid cell located adjacent to structure 310 may have a high connectivity value in the upward direction if open space extends far in that direction, but a low connectivity value in the area above structure 310 because structure 310 blocks movement or visibility from that direction.

FIG. 3B illustrates an example numerical representation of connectivity values assigned to each grid cell, demonstrating the extent of accessibility within a structured environment. Each number within the grid represents the maximum number of consecutive accessible cells extending in a particular direction before encountering an obstacle. The connectivity values are computed iteratively, considering a bottom-to-top scanning approach as an example. While FIG. 3B specifically illustrates connectivity evaluation in one direction, the same computation may be applied independently to all four principal directions—x-positive, x-negative, y-positive, and y-negative—as illustrated in FIG. 3C to construct a complete connectivity map.

To determine the connectivity level from bottom to top, the calculation may begin with the bottom row of the grid. If a cell is located at the bottom edge of the environment or is directly adjacent to an obstacle, it is assigned a connectivity value of 0, indicating that there are no accessible cells extending in that direction. If a cell has an accessible neighbor directly below it (i.e., in the direction of evaluation) with a connectivity value greater than or equal to zero, the cell inherits the neighbor's value incremented by one. This process continues iteratively for each row, moving upward through the grid, propagating connectivity values until an obstacle or the top boundary is reached.

For example, in FIG. 3B, the bottom-most row consists of 0s, indicating that these cells are either at the grid boundary or adjacent to an obstacle, preventing further connectivity in the upward direction. The next row evaluates each cell based on the values directly below it. If the corresponding lower cell is accessible (i.e., not an obstacle and has a value ≥0), the current cell's connectivity value is assigned as one greater than that of the cell below. This pattern continues throughout the entire grid, leading to a gradient of values where numbers increase as they extend farther from obstacles. The highest connectivity value recorded in FIG. 3B is 8, which means that from that position, there are eight consecutive accessible cells extending upward before an obstacle is encountered.

Regions surrounding structures 310, 311, 312, and 313 exhibit lower connectivity values due to the spatial constraints imposed by these obstacles. Cells that are completely obstructed—either forming part of a structure or falling into inaccessible regions—are assigned a value of −1, indicating they do not participate in connectivity calculations. This differentiation ensures that the algorithm does not falsely propagate accessibility through impassable regions.

Since FIG. 3B demonstrates only one direction of connectivity evaluation (bottom-to-top), a complete connectivity map may require performing this computation independently for each of the four principal directions. For instance, the same iterative method may be applied from top to bottom, left to right, and right to left. Each directional evaluation produces a separate connectivity grid that quantifies accessibility in the corresponding direction. The resulting four grids may then be combined or used independently, depending on the specific application requirements. By constructing multi-directional connectivity maps, the system may analyze spatial relationships more comprehensively, identifying high-connectivity regions that are ideal candidates for camera placement. In areas with large open spaces, the values remain consistently high, indicating regions that provide greater freedom of movement or unobstructed visibility in multiple directions. Conversely, values gradually decrease as they approach obstacles, which shows how connectivity is constrained by spatial elements.

FIG. 3C illustrates an example of how connectivity values are computed in four principal directions within a structured environment. The environment depicted in FIG. 3C includes structures placed within a grid-based spatial representation, similar to those illustrated in FIGS. 3A and 3B. The four images in FIG. 3C correspond to the connectivity evaluation in the x-positive, x-negative, y-positive, and y-negative directions. Each direction represents an independent computation of connectivity values, which determine the number of accessible grid cells extending outward from a given position before reaching an obstacle. In the x-positive direction, shown in image 330 of FIG. 3C, connectivity values are assigned based on how far a grid cell can extend to the bottom before encountering an obstruction. If a grid cell is unobstructed, its connectivity value increases incrementally based on the number of accessible cells that exist in the rightward direction. When an obstacle is encountered, the connectivity value resets, indicating that movement or visibility in that direction is blocked. The shading in this image represents the computed connectivity values, where brighter regions correspond to higher connectivity and darker regions correspond to lower connectivity. Similarly, image 340 of FIG. 3C represents the x-negative direction, where connectivity values are computed by evaluating the number of accessible grid cells extending to the top. Image 350 of FIG. 3C corresponds to the y-positive direction, in which connectivity values are determined based on the number of accessible cells extending rightward and image 360 of FIG. 3C represents the y-negative direction, where connectivity values are computed by evaluating how far a grid cell extends leftward before being obstructed.

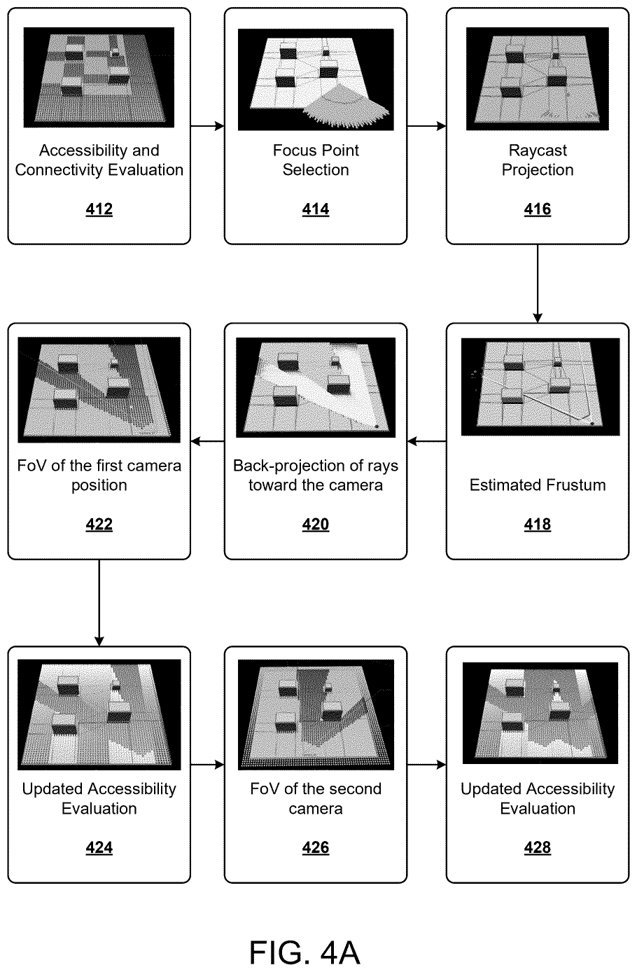

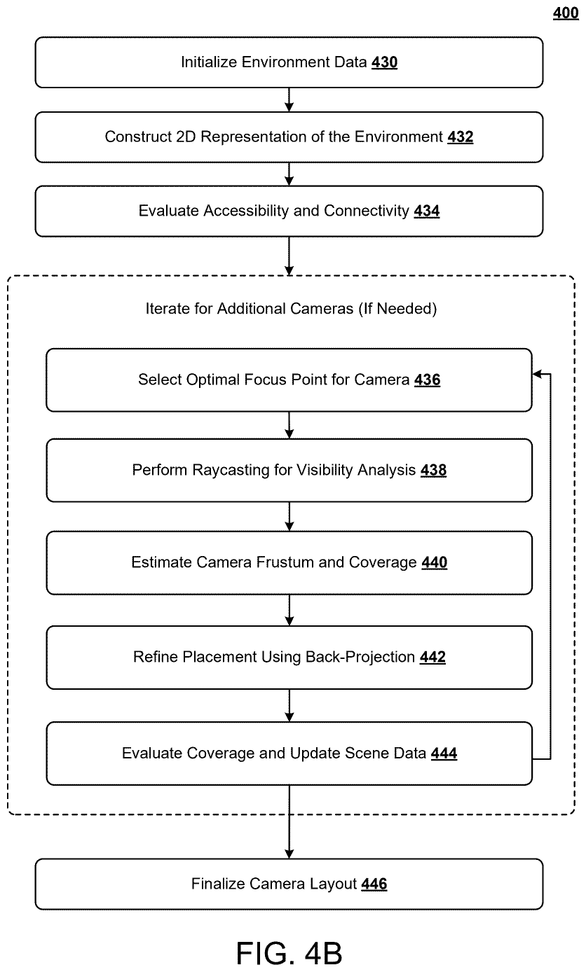

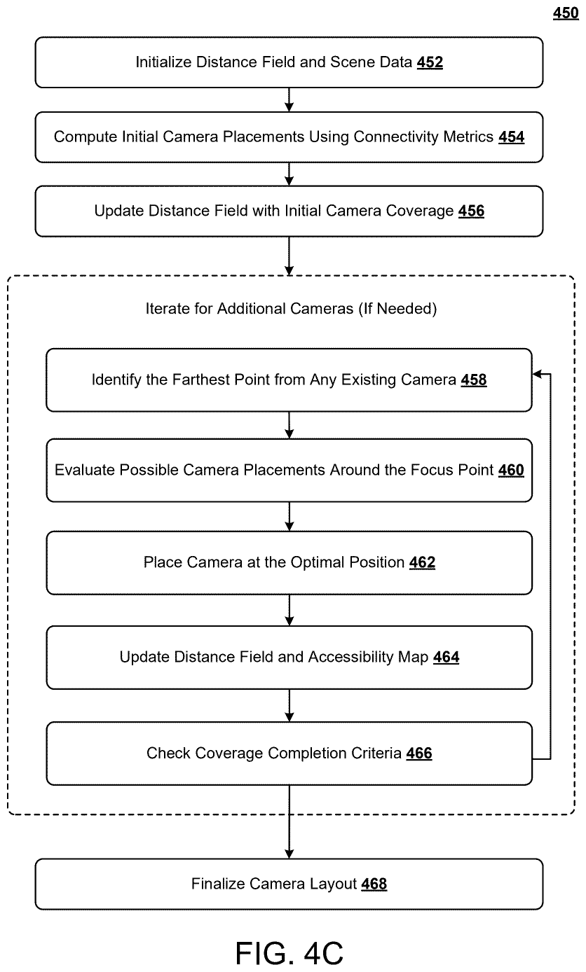

FIG. 4A illustrates an example process for determining camera placement through a sequence of steps, which may include accessibility and connectivity evaluation, focus point selection, raycasting projection, field-of-view (FoV) estimation, back-projection validation, and iterative accessibility updates. Such a process may refine camera placement iteratively by integrating spatial analysis, occlusion detection, and computational geometry techniques.

An example process may first evaluate 412 accessibility and connectivity within a given environment. This step may involve constructing a structured grid-based representation of the environment, where each grid cell corresponds to a specific spatial region. Cells coinciding with obstacles—such as buildings, furniture, or other structures—may be classified as inaccessible, while open areas may be designated as accessible. Once accessibility is determined, a connectivity analysis may be performed by computing the extent to which each accessible grid cell remains unobstructed in four principal directions: x-positive, x-negative, y-positive, and y-negative. Each cell may be assigned connectivity values based on the number of contiguous accessible cells in each direction.

With the connectivity map established, an optimal focus point for camera placement may be selected 414. A focus point may refer to a high-connectivity location that serves as the primary target for coverage optimization. The focus point selection may prioritize areas that provide maximum visibility of uncovered regions while minimizing redundant placements. If multiple grid cells exhibit similar connectivity values, additional selection criteria—such as distance from previously placed cameras, proximity to scene boundaries, or weighting of high-traffic areas—may be applied to refine the selection.

Once a focus point is identified, a raycasting projection may be performed 416 to determine feasible camera placement positions relative to the focus point. Raycasting may refer to a computational geometry technique that emits virtual rays from the selected focus point outward in multiple directions. These rays may simulate a camera's potential line of sight, allowing the system to detect obstructions and assess viable camera locations. Each candidate camera position may be evaluated based on multiple criteria, including unobstructed visibility, optimal positioning distance, and maximized coverage beyond focus point. For unobstructed visibility, the camera should maintain a direct line of sight to the focus point without being blocked by environmental objects. For optimal positioning distance, the camera-to-focus-point distance must fall within a predefined range to ensure an appropriate balance between coverage area and resolution. For maximized coverage beyond the focus point, placement is optimized to extend visibility beyond the immediate focus point, covering additional regions efficiently. If multiple valid camera positions are identified, they may be ranked based on occlusion minimization and total coverage contribution.

After selecting a viable camera position, such a process may estimate 418 the camera's frustum. A camera frustum may represent the three-dimensional volume of space visible to the camera, shaped like a truncated pyramid. The frustum computation may take into account the camera's intrinsic parameters, including focal length, sensor size, aspect ratio, and field-of-view angles. A projection matrix may be generated to transform the scene into camera coordinates, allowing for precise determination of which grid cells fall within the camera's visible area. This frustum estimation step may ensure that the camera placement effectively covers the intended region while conforming to optical constraints.

To further validate placement effectiveness, a back-projection analysis 420 of rays may be performed from observed regions toward the camera. This step may simulate how objects in the environment would appear from the camera's viewpoint and may verify that all designated areas within the frustum remain unobstructed. Back-projection techniques may involve tracing rays in the reverse direction—from the ground plane or designated points of interest—back toward the camera position. If an obstruction is detected along the path of a back-projected ray, the corresponding region may be marked as occluded, and adjustments to camera positioning may be considered. This validation step may ensure that the computed visibility reflects real-world constraints and prevents erroneous placements caused by overlooked occlusions.

Following back-projection validation, the actual field of view (FoV) 422 of the first camera position may be determined. While frustum estimation provides a theoretical viewing volume, real-world visibility may be constrained by occlusions or geometric interferences within the scene. A visibility mask may be applied to the grid, where each cell is evaluated based on whether it falls within the camera's final observable region. This refined FoV assessment may ensure that coverage computations align with practical scene constraints.

With the first camera placed and its FoV verified, such a process may update 424 the accessibility evaluation to reflect newly covered areas. The connectivity grid may be modified by reducing connectivity values in regions now visible to the camera. Previously unmonitored areas that are now covered may be removed from subsequent placement consideration such that additional cameras are deployed only in regions that remain uncovered. This iterative update may prevent redundant placements and dynamically refines the coverage strategy.

As coverage expands, such an iterative process may introduce 426 a second camera placement, following the same steps as illustrated in steps 414-424. A new focus point may be selected from the remaining uncovered areas, and raycasting may be performed to determine the next viable camera position. The frustum for this second camera may be computed to define its FoV such that its placement complements the first camera while minimizing gaps. This iterative placement process may extend coverage while maintaining non-overlapping placements.

Following the placement of the second camera, such a process may update 428 the accessibility evaluation once again, marking additional regions as covered. The connectivity grid may be further refined, and remaining uncovered areas may be prioritized for subsequent placements. This iterative refinement process may continue until all designated areas meet the predefined coverage criteria.

FIG. 4B illustrates an example process 400 that may be used for optimizing camera placement within an environment, in accordance with at least one embodiment. Process 400 may begin by initializing 430 environment data, where a 3D scene may be loaded, spatial constraints may be extracted, and a NavMesh may be generated to define accessible and non-accessible areas. The NavMesh may provide a structured reference for determining valid camera placement locations.

Next, process 400 may construct 432 a 2D representation of the environment by subdividing the space into a structured grid. Each grid cell may represent a discrete spatial unit, with accessibility data from the NavMesh applied to classify areas as either accessible or inaccessible. This transformation may enable a more computationally efficient placement strategy by simplifying spatial analysis while retaining key 3D information.

Following this, process 400 may evaluate 434 accessibility and connectivity by computing connectivity values for each accessible grid cell in four principal directions: x-positive, x-negative, y-positive, and y-negative. These values may quantify how well a grid cell is linked to open areas and assist in the identification of high-priority placement regions. By prioritizing high-connectivity areas, the placement approach may ensure effective scene coverage while minimizing occlusions.

To refine camera placement, process 400 may iterate within a feedback loop, as indicated by the dashed region in FIG. 4B. Within this loop, process 400 may select 436 an optimal focus point for camera placement. The selection process may prioritize areas with high connectivity that provide maximum coverage potential while considering previously placed cameras to avoid redundancy.

Once a focus point is determined, process 400 may perform 438 raycasting for visibility analysis. Rays may be projected outward from the selected focus point to assess line-of-sight constraints, detect occlusions, and validate whether the location allows for an unobstructed view of the target region.

With visibility confirmed, process 400 may estimate 440 the camera frustum and coverage. The field of view (FoV) may be determined based on predefined camera parameters, including focal length, orientation, and placement height. A frustum projection may be computed to establish the camera's expected coverage area within the scene.

To further refine the placement, process 400 may refine 442 the camera's position using back-projection techniques. This step may analyze how rays from the environment intersect with the camera's frustum and may adjust the camera's placement to enhance visibility while reducing occlusions.

Once the camera is positioned, process 400 may evaluate 444 the updated coverage and may modify the scene data accordingly. Newly covered regions may be marked and future placements may focus on remaining uncovered areas. If additional cameras are needed to achieve complete coverage, process 400 may return to selecting 436 the next focus point and may repeat the iterative process as indicated by the dashed steps.

When scene coverage reaches an optimal level, process 400 may finalize 446 the camera layout. The optimized camera positions and orientations may be stored for deployment in simulation environments or real-world applications with an efficient balance of coverage and computational efficiency.

FIG. 4C illustrates an example process 450, which may be utilized to optimize camera placement by employing a distance field-based approach. This example process may iteratively refine camera positioning by prioritizing underserved regions and dynamically updating placement decisions based on the shortest distance between cameras and uncovered points. By leveraging distance field computations in combination with raycasting and frustum estimation, process 450 may systematically minimize blind spots while ensuring efficient scene coverage.

Process 450 may begin with initializing 452 the distance field and scene data. The environment may be represented as a structured grid-based model, where each grid cell may be assigned an initial distance value that serves as a baseline metric for placement optimization. The initial distance values may be computed using the sum of the longest and shortest scene edges such that points farther from potential camera placements receive higher priority. By establishing a distance field representation, process 450 may define spatial relationships between uncovered areas and potential camera locations.

Following initialization, computing 454 initial camera placements may be performed using connectivity-based metrics. By analyzing high-connectivity areas within the environment, optimal starting positions for the first set of cameras may be identified. Raycasting may be employed to determine feasible camera placements that maximize visibility while minimizing occlusions. The placement of these initial cameras may serve as the foundation for subsequent iterations, ensuring that early placements contribute to an optimal coverage distribution.

Once initial placements are established, updating 456 the distance field may be performed to reflect newly covered areas. Such a process may compute the shortest distance from each accessible point to the nearest camera and dynamically adjust distance values to reflect updated coverage conditions. This iterative recalibration may enable continuous prioritization of regions with the least visibility, directing future placements toward areas requiring additional coverage.

Process 450 may then proceed with identifying 458 the farthest point from any existing camera. By scanning the updated distance field, the system may determine the most underserved region, selecting the point with the highest remaining distance value as the next candidate for camera placement. This targeted approach may ensure that additional cameras are introduced only in areas where they contribute the most significant improvement to coverage.

Once a focus point is selected, evaluating 460 potential camera placements may be conducted through raycasting analysis. This step may involve assessing multiple candidate positions surrounding the identified focus point, ensuring that each proposed placement maintains an unobstructed view of the designated area while also maximizing additional coverage. Candidate positions may be ranked based on their ability to minimize occlusions, increase scene visibility, and reduce overall distance values within the environment.

After identifying an optimal position, placing 462 the camera may be performed to enhance overall scene coverage. The selected camera position may be registered within the environment, allowing the system to integrate the new placement into the broader optimization strategy. By strategically positioning cameras to minimize the maximum distance between uncovered points and existing placements, process 450 may enable efficient coverage expansion while avoiding redundant placements.

Following camera placement, updating 464 the distance field and accessibility map may be executed to incorporate the newly covered areas into the scene representation. Distance values may be recomputed to reflect changes in coverage, ensuring that subsequent placements continue to prioritize areas with the least visibility. Additionally, modifications to the accessibility map may be performed to prevent redundant placements in regions already visible to deployed cameras.

At this stage, checking 466 whether the coverage criteria have been met may be conducted to determine if additional cameras are required. If uncovered areas remain beyond a predefined threshold, the system may return to the identification of the next farthest point, repeating the iterative placement process. If scene coverage meets the required criteria, the process may transition to finalization.

Upon reaching optimal coverage, finalizing 468 the camera layout may be performed to store the optimized positions and orientations. The final camera configuration may be output for deployment, simulation, or further refinement, ensuring that the placement strategy aligns with application-specific requirements. Through the integration of distance field computations, raycasting-based placement analysis, and iterative accessibility updates, process 450 may enable a structured and scalable approach to camera placement optimization, dynamically adapting to scene constraints while minimizing occlusions and redundant positioning.

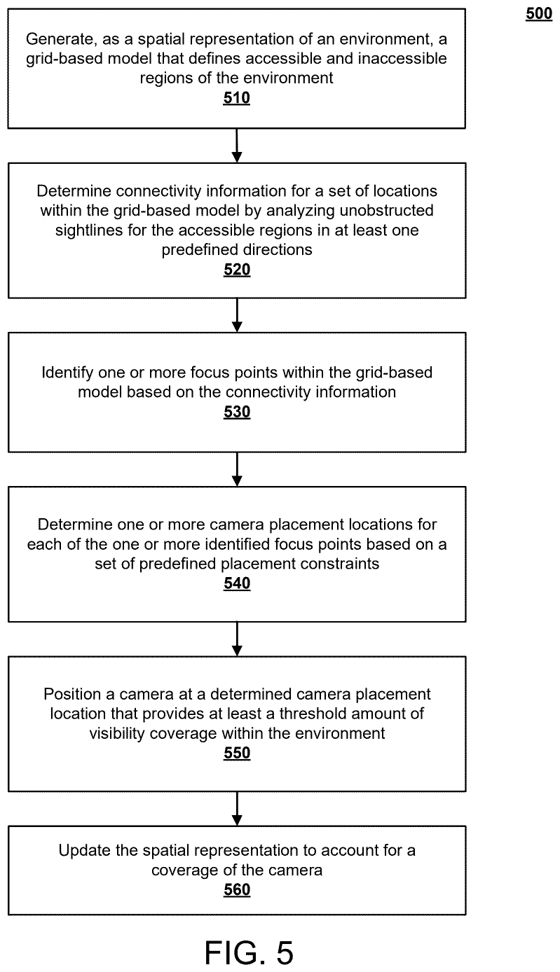

FIG. 5 illustrates process 500, which may be used to optimize camera placement within an environment by generating a structured spatial representation, computing connectivity information, identifying focus points, determining camera placements, positioning cameras, and updating the spatial model based on coverage. This step-by-step approach may ensure that placement decisions are informed by accessibility constraints, connectivity properties, and predefined placement conditions.

To begin, process 500 may generate 510 a grid-based model that provides a spatial representation of the environment by defining accessible and inaccessible regions. The environment may be partitioned into discrete grid cells, where each cell corresponds to a specific spatial region. Cells that coincide with obstacles, such as walls, furniture, or other objects, may be classified as inaccessible, while the remaining cells may be designated as accessible. This binary classification may allow for structured connectivity analysis and placement evaluation. The grid resolution may be selected based on the required spatial precision, with smaller grid cells allowing for finer placement granularity and larger cells offering computational efficiency.

Once the environment is represented as a grid-based model, process 500 may determine 520 connectivity information by analyzing the extent to which each accessible grid cell remains unobstructed in predefined directions. Connectivity values may represent the number of consecutive accessible cells extending outward in the x-positive, x-negative, y-positive, and y-negative directions. An iterative expansion process may compute these values, beginning at each grid cell and extending outward until encountering an obstacle. The resulting connectivity map may quantify spatial relationships between different regions, facilitating the identification of areas with high visibility potential.

Using the computed connectivity information, process 500 may identify 530 one or more focus points within the grid-based model. A focus point may serve as a primary target for camera placement, ensuring that a camera positioned at a designated location maintains a direct line of sight to a region of interest. If multiple candidate focus points exhibit similar connectivity properties, additional criteria such as scene importance, proximity to uncovered areas, or spatial distribution constraints may refine the selection.

After identifying the focus points, process 500 may determine 540 one or more candidate camera placement locations based on predefined constraints. These constraints may include minimum and maximum camera-to-focus-point distances, allowable camera orientations, and visibility requirements. A set of candidate positions may be evaluated using a raycasting process, in which virtual rays are emitted from the focus point to detect obstructions and assess placement feasibility. Candidate camera positions may be ranked based on their ability to maintain an unobstructed view of the focus point while maximizing additional coverage. The final placement location may be selected based on a weighted evaluation of coverage efficiency, occlusion avoidance, and compliance with placement constraints.

With a placement location selected, process 500 may position 550 a camera to provide at least a threshold amount of visibility coverage within the environment. Once placed, the camera's field of view may be computed based on intrinsic parameters such as focal length, aspect ratio, and sensor size. A frustum projection may estimate the coverage area, and a back-projection analysis may validate whether the designated focus point falls within the observable region. If computed visibility does not meet predefined coverage thresholds, iterative adjustments may refine placement to ensure sufficient scene coverage.

Following the placement of a camera, process 500 may update 560 the spatial representation to account for the newly covered regions. The grid-based model may be modified to mark areas now visible to the camera, preventing redundant placements in subsequent iterations. Connectivity values for previously uncovered regions may be recalculated to reflect updated visibility such that remaining uncovered areas are prioritized in the next placement iteration. This refinement process may continue iteratively until all required regions meet the predefined visibility criteria.

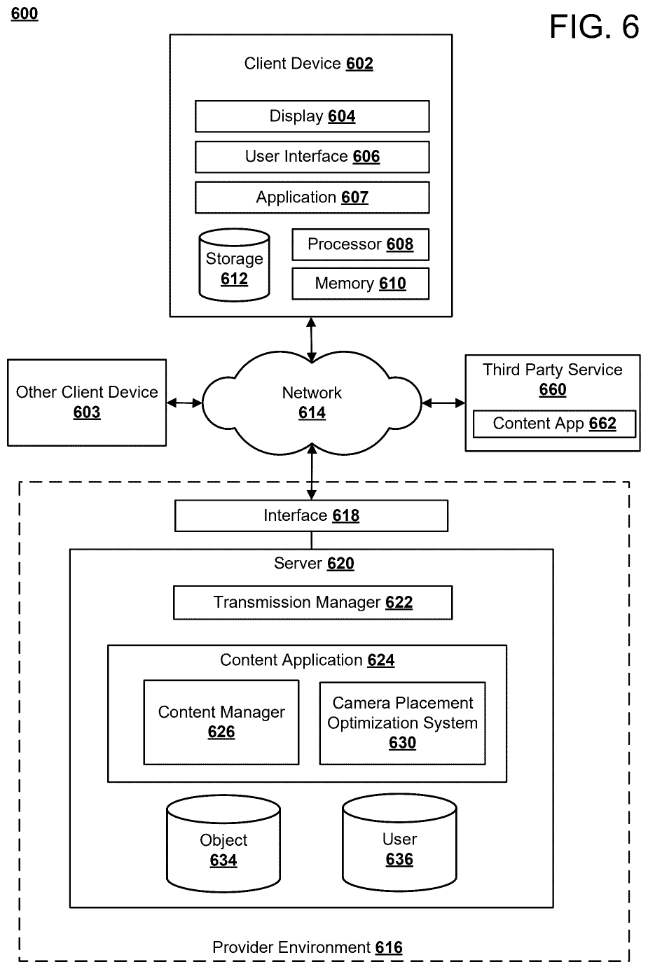

FIG. 6 illustrates an example networked system 600 that includes a hardware design optimization system, in accordance with various embodiments. The example networked system 600 can be used to provide, generate, modify, encode, process, and/or transmit data or other content. The example networked system 600 may include a client device 602, other client device 603, a network 614, a third party service 660, and a provider environment 616 that includes a camera placement optimization system 630.

The client device 602 may generate or receive data for a session using components of an application 607 on client device 602 and data stored locally on that client device 602. As an example, a user may utilize a client device 602 to optimize camera placement using the application 607. Although only one client device 602 is illustrated in detail, the example networked system 600 may include one or more other client devices 603 that can communicate with the provider environment 616 through the network 614. A client device 602 may be any appropriate computing device capable of enabling a user to perform tasks related to optimizing camera placements as discussed herein, such as may include a desktop computer, notebook computer, computer workstation, gaming console, set-top box, streaming device, smartphone, tablet computer, VR headset, AR goggles, wearable computer, or a smart television. In at least one embodiment, a user can access functionality related to optimizing camera placements using a user interface (UI) 606 running on a client device 602, although at least some functionality may also operate on a remote device, networked device, or through a cloud computing platform. In at least one embodiment, a user can provide input to the UI 606, such as through a touch-sensitive display 604 or by moving a mouse cursor displayed on a display screen. In one embodiment, a user may be able to provide inputs such as preferences and configuration data to an application 607. The application 607 may be provided by the provider environment 616 for the user to download on the client device 602. In at least one embodiment, a client device can include at least one processor 608 (e.g., a CPU or GPU), a storage 612, and a memory 610 to execute application 607 and/or perform tasks on behalf of application 607.

In one embodiment, each client device 602 can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by enabling the client devices to interact with servers that are in closer proximity, while also improving security of resources in the cloud provider environment.

The network 614 may represent the communication pathways among the client device 602, the provider environment 616, other client device 603, and the third party service 660. Through the network 614, the client device 602 may send input information associated with stream data processing over the network 614. The information may be received by a remote computing system, as may be part of a resource provider environment 616. In one embodiment, the network 614 is the Internet. The network 614 can include any appropriate network, including an intranet, Internet, a cellular network, a local area network (LAN), or any other such network or combination, and communication over a network can be enabled via wired and/or wireless connections. The network 614 can also utilize dedicated or private communication links that are not necessarily part of the Internet. In one embodiment, the network 614 uses standard communications technologies and/or protocols. Thus, the network 614 can include links using technologies such as Ethernet, Wi-Fi, integrated services digital network (ISDN), digital subscriber lines (DSL), asynchronous transfer mode (ATM), etc. Similarly, the networking protocols used on the network 614 can include multiprotocol label switching (MPLS), the transmission control protocol/Internet protocol (TCP/IP), the hypertext transport protocol (HTTP), the simple mail transfer protocol (SMTP), the file transfer protocol (FTP), etc. In one embodiment, at least some of the links use mobile networking technologies, such as long term evolution (LTE). The data exchanged over the network 614 can be represented using technologies or formats including the hypertext markup language (XML), the wireless access protocol (WAP), the short message service (SMS) etc. In addition, all or some of the links can be encrypted using conventional encryption technologies such as the secure sockets layer (SSL), secure HTTP or virtual private networks (VPNs). In another embodiment, the client device 602 can use custom and/or dedicated data communications technologies instead of, or in addition to, the ones described above.

The provider environment 616 may include any appropriate components for receiving requests and returning information or performing actions in response to those requests. In the embodiment illustrated in FIG. 6, the provider environment 616 may include an interface 618, and a server 620 that include various components for performing tasks associated with optimizing camera placements. In at least one embodiment, the provider environment 616 might include Web servers and/or application servers for receiving and processing requests, then returning data or other content or information in response to a request.

The interface 618 may receive communications to the server 620. In at least one embodiment, the interface 618 can include application programming interfaces (APIs) or other exposed interfaces enabling a user to submit requests to the server 620. In at least one embodiment, the interface 618 can include other components as well, such as at least one Web server, routing components, or load balancers. In at least one embodiment, components of an interface 618 can determine a type of request or communication, and can direct a request to an appropriate system or service such as a camera placement optimization system 630.

The server 620 may include a transmission manager 622, a content application 624, an object repository 634, and a user database 636. The server 620 may receive requests and data from the client device 602, perform tasks associated with the requests, and send results or other data to the client device 602. In at least one embodiment, a content application 624 executing on the server 620 (e.g., a cloud server or edge server) may initiate a session associated with the client device 602, as may use a session manager and user data stored in a user database 636, and can cause content such as one or more object representations from an object repository 634 to be selected by a content manager 626 for processing. At least a portion of the generated content, such as results from stream data processing may be transmitted to the client device 602 using an appropriate transmission manager 622 to send by download, streaming, or another such transmission channel. An encoder may be used to encode and/or compress at least some of this data before transmitting to the client device 602. In at least one embodiment, the client device 602 receiving such content can provide this content to a corresponding application 607 for selecting, providing, synthesizing, modifying, or using content for presentation (or other purposes) on or by the client device 602. A decoder may also be used to decode data received over the network 614 for presentation via client device 602, such as image or video content through a touch-sensitive display 604. In at least one embodiment, at least some of the content may already be stored on, rendered on, or accessible to client device 602 such that transmission over the network 614 is not required for at least that portion of content, such as where the content may have been previously downloaded or stored locally on a hard drive or optical disk. In at least one embodiment, a transmission mechanism such as data streaming can be used to transfer the content from the server 620, or user database 636, to client device 602. In at least one embodiment, at least a portion of this content can be obtained, enhanced, and/or streamed from another source, such as a third party service 660 or other client device 603, that may also include a content application 662 for generating, enhancing, or providing content. In at least one embodiment, portions of this functionality can be performed using multiple computing devices, or multiple processors within one or more computing devices, such as may include a combination of CPUs and GPUs.

In at least one embodiment, the server 620 may include a processor such as a central processing unit (CPU). In at least one embodiment, however, resources in such environments can utilize GPUs to process data for at least certain types of requests. In at least one embodiment, with thousands of cores, GPUs are designed to handle substantial parallel workloads and, therefore, have become popular in deep learning for training neural networks and generating predictions. In at least one embodiment, while use of GPUs for offline builds has enabled faster training of larger and more complex models, generating predictions offline implies that either request-time input features cannot be used or predictions must be generated for all permutations of features and stored in a lookup table to serve real-time requests. In at least one embodiment, if a deep learning framework supports a CPU-mode and a model is small and simple enough to perform a feed-forward on a CPU with a reasonable latency, then a service on a CPU instance could host a model. In at least one embodiment, training can be done offline on a GPU and inference done in real-time on a CPU. In at least one embodiment, if a CPU approach is not a viable option, then a service can run on a GPU instance. In at least one embodiment, because GPUs have different performance and cost characteristics than CPUs, however, running a service that offloads a runtime algorithm to a GPU can require it to be designed differently from a CPU based service.

The server 620 may include a content application 624 that includes a content manager 626 and a camera placement optimization system 630. As discussed previously, the content manager 626 may send objects, such as datasets and instructions, from the object repository 634 along with requests and other data from the client device 602 to a camera placement optimization system 630 for stream data processing. A camera placement optimization system 630 may process input data and provide the results to the transmission manager 622 for sending back to the client device 602. A camera placement optimization system 630 may also use local datasets or datasets provided by the third party service 660 for stream data processing.

### Inference and Training Logic

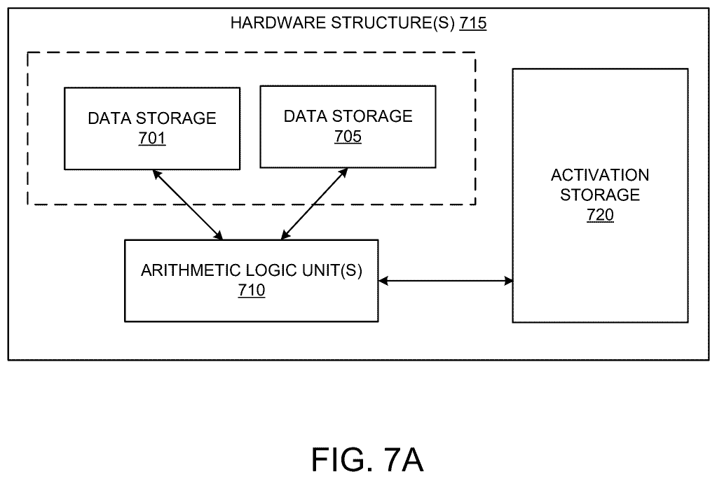

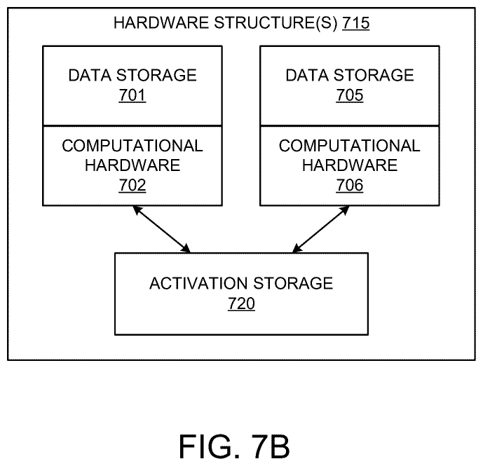

FIG. 7A illustrates inference and/or training logic 715 used to perform inferencing and/or training operations associated with one or more embodiments. Details regarding inference and/or training logic 715 are provided below in conjunction with FIGS. 7A and/or 7B.

In at least one embodiment, inference and/or training logic 715 may include, without limitation, code and/or data storage 701 to store forward and/or output weight and/or input/output data, and/or other parameters to configure neurons or layers of a neural network trained and/or used for inferencing in aspects of one or more embodiments. In at least one embodiment, training logic 715 may include, or be coupled to code and/or data storage 701 to store graph code or other software to control timing and/or order, in which weight and/or other parameter information is to be loaded to configure, logic, including integer and/or floating point units (collectively, arithmetic logic units (ALUs). In at least one embodiment, code, such as graph code, loads weight or other parameter information into processor ALUs based on an architecture of a neural network to which the code corresponds. In at least one embodiment, code and/or data storage 701 stores weight parameters and/or input/output data of each layer of a neural network trained or used in conjunction with one or more embodiments during forward propagation of input/output data and/or weight parameters during training and/or inferencing using aspects of one or more embodiments. In at least one embodiment, any portion of code and/or data storage 701 may be included with other on-chip or off-chip data storage, including a processor's L1, L2, or L3 cache or system memory.

In at least one embodiment, any portion of code and/or data storage 701 may be internal or external to one or more processors or other hardware logic devices or circuits. In at least one embodiment, code and/or data storage 701 may be cache memory, dynamic randomly addressable memory (“DRAM”), static randomly addressable memory (“SRAM”), non-volatile memory (e.g., Flash memory), or other storage. In at least one embodiment, choice of whether code and/or data storage 701 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 715 may include, without limitation, a code and/or data storage 705 to store backward and/or output weight and/or input/output data corresponding to neurons or layers of a neural network trained and/or used for inferencing in aspects of one or more embodiments. In at least one embodiment, code and/or data storage 705 stores weight parameters and/or input/output data of each layer of a neural network trained or used in conjunction with one or more embodiments during backward propagation of input/output data and/or weight parameters during training and/or inferencing using aspects of one or more embodiments. In at least one embodiment, training logic 715 may include, or be coupled to code and/or data storage 705 to store graph code or other software to control timing and/or order, in which weight and/or other parameter information is to be loaded to configure, logic, including integer and/or floating point units (collectively, arithmetic logic units (ALUs). In at least one embodiment, code, such as graph code, loads weight or other parameter information into processor ALUs based on an architecture of a neural network to which the code corresponds. In at least one embodiment, any portion of code and/or data storage 705 may be included with other on-chip or off-chip data storage, including a processor's L1, L2, or L3 cache or system memory. In at least one embodiment, any portion of code and/or data storage 705 may be internal or external to on one or more processors or other hardware logic devices or circuits. In at least one embodiment, code and/or data storage 705 may be cache memory, DRAM, SRAM, non-volatile memory (e.g., Flash memory), or other storage. In at least one embodiment, choice of whether code and/or data storage 705 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, code and/or data storage 701 and code and/or data storage 705 may be separate storage structures. In at least one embodiment, code and/or data storage 701 and code and/or data storage 705 may be same storage structure. In at least one embodiment, code and/or data storage 701 and code and/or data storage 705 may be partially same storage structure and partially separate storage structures. In at least one embodiment, any portion of code and/or data storage 701 and code and/or data storage 705 may be included with other on-chip or off-chip data storage, including a processor's L1, L2, or L3 cache or system memory.

In at least one embodiment, inference and/or training logic 715 may include, without limitation, one or more arithmetic logic unit(s) (“ALU(s)”) 710, including integer and/or floating point units, to perform logical and/or mathematical operations based, at least in part on, or indicated by, training and/or inference code (e.g., graph code), a result of which may produce activations (e.g., output values from layers or neurons within a neural network) stored in an activation storage 720 that are functions of input/output and/or weight parameter data stored in code and/or data storage 701 and/or code and/or data storage 705. In at least one embodiment, activations stored in activation storage 720 are generated according to linear algebraic and or matrix-based mathematics performed by ALU(s) 710 in response to performing instructions or other code, wherein weight values stored in code and/or data storage 705 and/or code and/or data storage 701 are used as operands along with other values, such as bias values, gradient information, momentum values, or other parameters or hyperparameters, any or all of which may be stored in code and/or data storage 705 or code and/or data storage 701 or another storage on or off-chip.

In at least one embodiment, ALU(s) 710 are included within one or more processors or other hardware logic devices or circuits, whereas in another embodiment, ALU(s) 710 may be external to a processor or other hardware logic device or circuit that uses them (e.g., a co-processor). In at least one embodiment, ALU(s) 710 may be included within a processor's execution units or otherwise within a bank of ALUs accessible by a processor's execution units either within same processor or distributed between different processors of different types (e.g., central processing units, graphics processing units, fixed function units, etc.). In at least one embodiment, code and/or data storage 701, code and/or data storage 705, and activation storage 720 may be on same processor or other hardware logic device or circuit, whereas in another embodiment, they may be in different processors or other hardware logic devices or circuits, or some combination of same and different processors or other hardware logic devices or circuits. In at least one embodiment, any portion of activation storage 720 may be included with other on-chip or off-chip data storage, including a processor's L1, L2, or L3 cache or system memory. Furthermore, inferencing and/or training code may be stored with other code accessible to a processor or other hardware logic or circuit and fetched and/or processed using a processor's fetch, decode, scheduling, execution, retirement and/or other logical circuits.

In at least one embodiment, activation storage 720 may be cache memory, DRAM, SRAM, non-volatile memory (e.g., Flash memory), or other storage. In at least one embodiment, activation storage 720 may be completely or partially within or external to one or more processors or other logical circuits. In at least one embodiment, choice of whether activation storage 720 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors. In at least one embodiment, inference and/or training logic 715 illustrated in FIG. 7A may be used in conjunction with an application-specific integrated circuit (“ASIC”), such as Tensorflow® Processing Unit from Google, an inference processing unit (IPU) from Graphcore™, or a Nervana® (e.g., “Lake Crest”) processor from Intel Corp. In at least one embodiment, inference and/or training logic 715 illustrated in FIG. 7A may be used in conjunction with central processing unit (“CPU”) hardware, graphics processing unit (“GPU”) hardware or other hardware, such as field programmable gate arrays (“FPGAs”).

FIG. 7B illustrates inference and/or training logic 715, according to at least one or more embodiments. In at least one embodiment, inference and/or training logic 715 may include, without limitation, hardware logic in which computational resources are dedicated or otherwise exclusively used in conjunction with weight values or other information corresponding to one or more layers of neurons within a neural network. In at least one embodiment, inference and/or training logic 715 illustrated in FIG. 7B may be used in conjunction with an application-specific integrated circuit (ASIC), such as Tensorflow® Processing Unit from Google, an inference processing unit (IPU) from Graphcore™, or a Nervana® (e.g., “Lake Crest”) processor from Intel Corp. In at least one embodiment, inference and/or training logic 715 illustrated in FIG. 7B may be used in conjunction with central processing unit (CPU) hardware, graphics processing unit (GPU) hardware or other hardware, such as field programmable gate arrays (FPGAs). In at least one embodiment, inference and/or training logic 715 includes, without limitation, code and/or data storage 701 and code and/or data storage 705, which may be used to store code (e.g., graph code), weight values and/or other information, including bias values, gradient information, momentum values, and/or other parameter or hyperparameter information. In at least one embodiment illustrated in FIG. 7B, each of code and/or data storage 701 and code and/or data storage 705 is associated with a dedicated computational resource, such as computational hardware 702 and computational hardware 706, respectively. In at least one embodiment, each of computational hardware 702 and computational hardware 706 comprises one or more ALUs that perform mathematical functions, such as linear algebraic functions, only on information stored in code and/or data storage 701 and code and/or data storage 705, respectively, result of which is stored in activation storage 720.

In at least one embodiment, each of code and/or data storage 701 and 705 and corresponding computational hardware 702 and 706, respectively, correspond to different layers of a neural network, such that resulting activation from one “storage/computational pair 701/702” of code and/or data storage 701 and computational hardware 702 is provided as an input to “storage/computational pair 705/706” of code and/or data storage 705 and computational hardware 706, in order to mirror conceptual organization of a neural network. In at least one embodiment, each of storage/computational pairs 701/702 and 705/706 may correspond to more than one neural network layer. In at least one embodiment, additional storage/computation pairs (not shown) subsequent to or in parallel with storage computation pairs 701/702 and 705/706 may be included in inference and/or training logic 715.

### Data Center

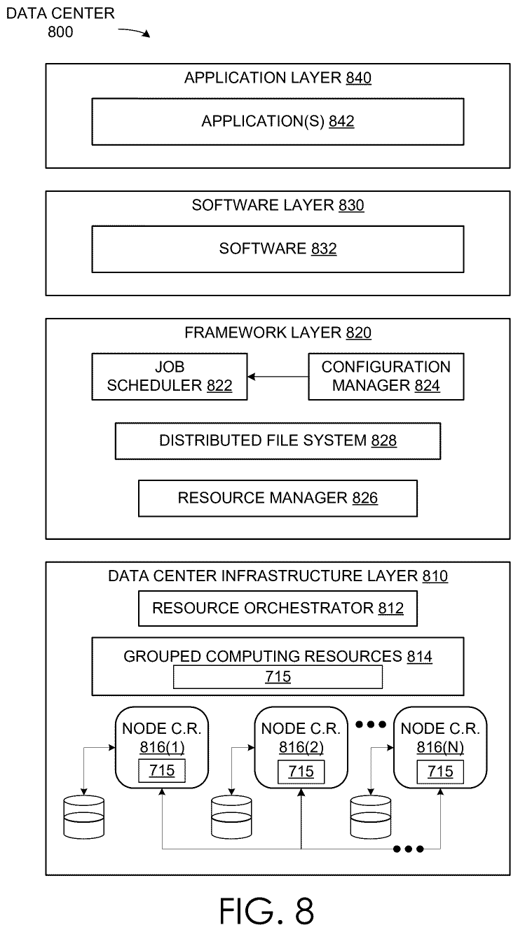

FIG. 8 illustrates an example data center 800, in which at least one embodiment may be used. In at least one embodiment, data center 800 includes a data center infrastructure layer 810, a framework layer 820, a software layer 830, and an application layer 840.

In at least one embodiment, as shown in FIG. 8, data center infrastructure layer 810 may include a resource orchestrator 812, grouped computing resources 814, and node computing resources (“node C.R.s”) 816(1)-816(N), where “N” represents any whole, positive integer. In at least one embodiment, node C.R.s 816(1)-816(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 816(1)-816(N) may be a server having one or more of above-mentioned computing resources.

In at least one embodiment, grouped computing resources 814 may include separate groupings of node C.R.s housed within one or more racks (not shown), or many racks housed in data centers at various geographical locations (also not shown). Separate groupings of node C.R.s within grouped computing resources 814 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 812 may configure or otherwise control one or more node C.R.s 816(1)-816(N) and/or grouped computing resources 814. In at least one embodiment, resource orchestrator 812 may include a software design infrastructure (“SDI”) management entity for data center 800. In at least one embodiment, resource orchestrator 812 may include hardware, software or some combination thereof.

In at least one embodiment, as shown in FIG. 8, framework layer 820 includes a job scheduler 822, a configuration manager 824, a resource manager 826 and a distributed file system 828. In at least one embodiment, framework layer 820 may include a framework to support software 832 of software layer 830 and/or one or more application(s) 842 of application layer 840. In at least one embodiment, software 832 or application(s) 842 may respectively include web-based service software or applications, such as those provided by Amazon Web Services, Google Cloud and Microsoft Azure. In at least one embodiment, framework layer 820 may be, but is not limited to, a type of free and open-source software web application framework such as Apache Spark™ (hereinafter “Spark”) that may use distributed file system 828 for large-scale data processing (e.g., “big data”). In at least one embodiment, job scheduler 822 may include a Spark driver to facilitate scheduling of workloads supported by various layers of data center 800. In at least one embodiment, configuration manager 824 may be capable of configuring different layers such as software layer 830 and framework layer 820 including Spark and distributed file system 828 for supporting large-scale data processing. In at least one embodiment, resource manager 826 may be capable of managing clustered or grouped computing resources mapped to or allocated for support of distributed file system 828 and job scheduler 822. In at least one embodiment, clustered or grouped computing resources may include grouped computing resource 814 at data center infrastructure layer 810. In at least one embodiment, resource manager 826 may coordinate with resource orchestrator 812 to manage these mapped or allocated computing resources.

In at least one embodiment, software 832 included in software layer 830 may include software used by at least portions of node C.R.s 816(1)-816(N), grouped computing resources 814, and/or distributed file system 828 of framework layer 820. The one or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 828 of framework layer 820. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 824, resource manager 826, and resource orchestrator 812 may implement any number and type of self-modifying actions based on any amount and type of data acquired in any technically feasible fashion. In at least one embodiment, self-modifying actions may relieve a data center operator of data center 800 from making possibly bad configuration decisions and possibly avoiding underused and/or poor performing portions of a data center.

In at least one embodiment, data center 800 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 800. In at least one embodiment, trained machine learning models corresponding to one or more neural networks may be used to infer or predict information using resources described above with respect to data center 800 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 715 are used to perform inferencing and/or training operations associated with one or more embodiments. Details regarding inference and/or training logic 715 are provided below in conjunction with FIGS. 7A and/or 7B. In at least one embodiment, inference and/or training logic 715 may be used in system FIG. 8 for inferencing or predicting operations based, at least in part, on weight parameters calculated using neural network training operations, neural network functions and/or architectures, or neural network use cases described herein.

Such components can allow for multi-frame interpolation for improved user experience.

### Computer Systems

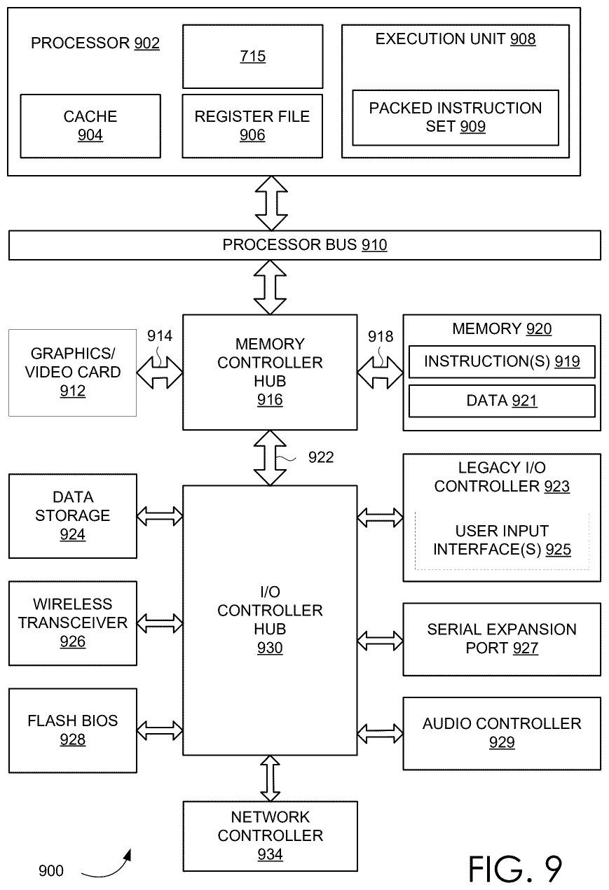

FIG. 9 is a block diagram illustrating an exemplary computer system, which may be a system with interconnected devices and components, a system-on-a-chip (SOC) or some combination thereof 900 formed with a processor that may include execution units to execute an instruction, according to at least one embodiment. In at least one embodiment, computer system 900 may include, without limitation, a component, such as a processor 902 to employ execution units including logic to perform algorithms for process data, in accordance with present disclosure, such as in embodiment described herein. In at least one embodiment, computer system 900 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 900 may execute a version of WINDOWS′ operating system available from Microsoft Corporation of Redmond, Wash., although other operating systems (UNIX and Linux for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 900 may include, without limitation, processor 902 that may include, without limitation, one or more execution units 908 to perform machine learning model training and/or inferencing according to techniques described herein. In at least one embodiment, computer system 900 is a single processor desktop or server system, but in another embodiment computer system 900 may be a multiprocessor system. In at least one embodiment, processor 902 may include, without limitation, a complex instruction set computing (“CISC”) microprocessor, a reduced instruction set computing (“RISC”) microprocessor, a very long instruction word (“VLIW”) computing microprocessor, a processor implementing a combination of instruction sets, or any other processor device, such as a digital signal processor, for example. In at least one embodiment, processor 902 may be coupled to a processor bus 910 that may transmit data signals between processor 902 and other components in computer system 900.

In at least one embodiment, processor 902 may include, without limitation, a Level 1 (“L1”) internal cache memory (“cache”) 904. In at least one embodiment, processor 902 may have a single internal cache or multiple levels of internal cache. In at least one embodiment, cache memory may reside external to processor 902. Other embodiments may also include a combination of both internal and external caches depending on particular implementation and needs. In at least one embodiment, register file 906 may store different types of data in various registers including, without limitation, integer registers, floating point registers, status registers, and instruction pointer register.

In at least one embodiment, execution unit 908, including, without limitation, logic to perform integer and floating point operations, also resides in processor 902. In at least one embodiment, processor 902 may also include a microcode (“ucode”) read only memory (“ROM”) that stores microcode for certain macro instructions. In at least one embodiment, execution unit 908 may include logic to handle a packed instruction set 909. In at least one embodiment, by including packed instruction set 909 in an instruction set of a general-purpose processor 902, along with associated circuitry to execute instructions, operations used by many multimedia applications may be performed using packed data in a general-purpose processor 902. In one or more embodiments, many multimedia applications may be accelerated and executed more efficiently by using full width of a processor's data bus for performing operations on packed data, which may eliminate need to transfer smaller units of data across processor's data bus to perform one or more operations one data element at a time.

In at least one embodiment, execution unit 908 may also be used in microcontrollers, embedded processors, graphics devices, DSPs, and other types of logic circuits. In at least one embodiment, computer system 900 may include, without limitation, a memory 920. In at least one embodiment, memory 920 may be implemented as a Dynamic Random Access Memory (“DRAM”) device, a Static Random Access Memory (“SRAM”) device, flash memory device, or other memory device. In at least one embodiment, memory 920 may store instruction(s) 919 and/or data 921 represented by data signals that may be executed by processor 902.

In at least one embodiment, system logic chip may be coupled to processor bus 910 and memory 920. In at least one embodiment, system logic chip may include, without limitation, a memory controller hub (“MCH”) 916, and processor 902 may communicate with MCH 916 via processor bus 910. In at least one embodiment, MCH 916 may provide a high bandwidth memory path 918 to memory 920 for instruction and data storage and for storage of graphics commands, data and textures. In at least one embodiment, MCH 916 may direct data signals between processor 902, memory 920, and other components in computer system 900 and to bridge data signals between processor bus 910, memory 920, and a system I/O 922. In at least one embodiment, system logic chip may provide a graphics port for coupling to a graphics controller. In at least one embodiment, MCH 916 may be coupled to memory 920 through a high bandwidth memory path 918 and graphics/video card 912 may be coupled to MCH 916 through an Accelerated Graphics Port (“AGP”) interconnect 914.

In at least one embodiment, computer system 900 may use system I/O 922 that is a proprietary hub interface bus to couple MCH 916 to I/O controller hub (“ICH”) 930. In at least one embodiment, ICH 930 may provide direct connections to some I/O devices via a local I/O bus. In at least one embodiment, local I/O bus may include, without limitation, a high-speed I/O bus for connecting peripherals to memory 920, chipset, and processor 902. Examples may include, without limitation, an audio controller 929, a firmware hub (“flash BIOS”) 928, a wireless transceiver 926, a data storage 924, a legacy I/O controller 923 containing user input and keyboard interfaces 925, a serial expansion port 927, such as Universal Serial Bus (“USB”), and a network controller 934. Data storage 924 may comprise a hard disk drive, a floppy disk drive, a CD-ROM device, a flash memory device, or other mass storage device.

In at least one embodiment, FIG. 9 illustrates a system, which includes interconnected hardware devices or “chips”, whereas in other embodiments, FIG. 9 may illustrate an exemplary System on a Chip (“SoC”). In at least one embodiment, devices may be interconnected with proprietary interconnects, standardized interconnects (e.g., PCIe) or some combination thereof. In at least one embodiment, one or more components of computer system 900 are interconnected using compute express link (CXL) interconnects.

Inference and/or training logic 715 are used to perform inferencing and/or training operations associated with one or more embodiments. Details regarding inference and/or training logic 715 are provided below in conjunction with FIGS. 7A and/or 7B. In at least one embodiment, inference and/or training logic 715 may be used in system FIG. 9 for inferencing or predicting operations based, at least in part, on weight parameters calculated using neural network training operations, neural network functions and/or architectures, or neural network use cases described herein.

Such components can allow for optimizing camera placements for improved user experience.

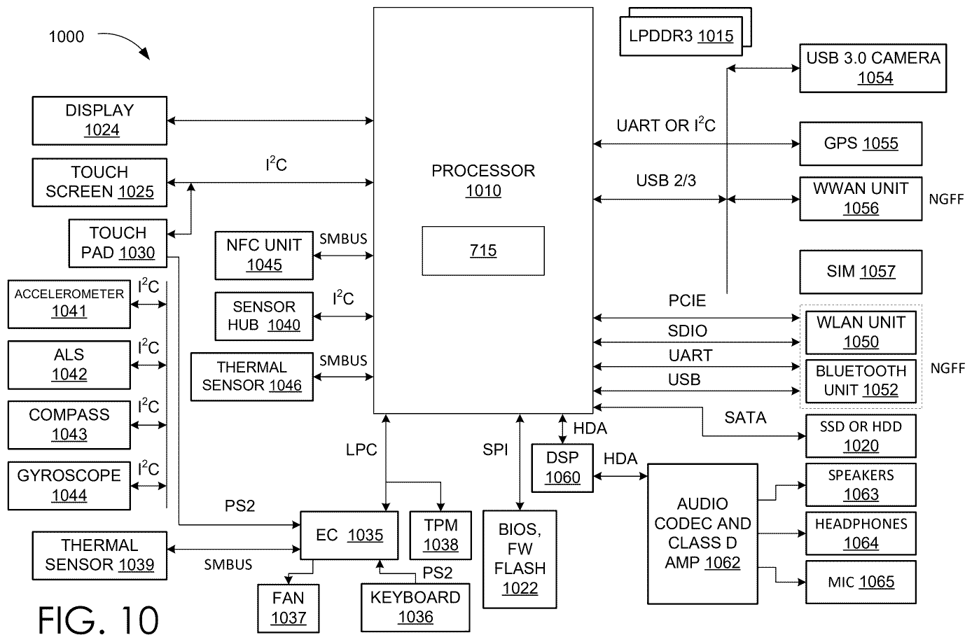

FIG. 10 is a block diagram illustrating an electronic device 1000 for utilizing a processor 1010, according to at least one embodiment. In at least one embodiment, electronic device 1000 may be, for example and without limitation, a notebook, a tower server, a rack server, a blade server, a laptop, a desktop, a tablet, a mobile device, a phone, an embedded computer, or any other suitable electronic device.

In at least one embodiment, electronic device 1000 may include, without limitation, processor 1010 communicatively coupled to any suitable number or kind of components, peripherals, modules, or devices. In at least one embodiment, processor 1010 coupled using a bus or interface, such as a 1° C. bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3), or a Universal Asynchronous Receiver/Transmitter (“UART”) bus. In at least one embodiment, FIG. 10 illustrates a system, which includes interconnected hardware devices or “chips”, whereas in other embodiments, FIG. 10 may illustrate an exemplary System on a Chip (“SoC”). In at least one embodiment, devices illustrated in FIG. 10 may be interconnected with proprietary interconnects, standardized interconnects (e.g., PCIe) or some combination thereof. In at least one embodiment, one or more components of FIG. 10 are interconnected using compute express link (CXL) interconnects.

In at least one embodiment, FIG. 10 may include a display 1024, a touch screen 1025, a touch pad 1030, a Near Field Communications unit (“NFC”) 1045, a sensor hub 1040, a thermal sensor 1046, an Express Chipset (“EC”) 1035, a Trusted Platform Module (“TPM”) 1038, BIOS/firmware/flash memory (“BIOS, FW Flash”) 1022, a DSP 1060, a drive 1020 such as a Solid State Disk (“SSD”) or a Hard Disk Drive (“HDD”), a wireless local area network unit (“WLAN”) 1050, a Bluetooth unit 1052, a Wireless Wide Area Network unit (“WWAN”) 1056, a Global Positioning System (GPS) 1055, a camera (“USB 3.0 camera”) 1054 such as a USB 3.0 camera, and/or a Low Power Double Data Rate (“LPDDR”) memory unit (“LPDDR3”) 1015 implemented in, for example, LPDDR3 standard. These components may each be implemented in any suitable manner.

In at least one embodiment, other components may be communicatively coupled to processor 1010 through components discussed above. In at least one embodiment, an accelerometer 1041, Ambient Light Sensor (“ALS”) 1042, compass 1043, and a gyroscope 1044 may be communicatively coupled to sensor hub 1040. In at least one embodiment, thermal sensor 1039, a fan 1037, a keyboard 1036, and a touch pad 1030 may be communicatively coupled to EC 1035. In at least one embodiment, speakers 1063, headphones 1064, and microphone (“mic”) 1065 may be communicatively coupled to an audio unit (“audio codec and class d amp”) 1062, which may in turn be communicatively coupled to DSP 1060. In at least one embodiment, audio unit 1062 may include, for example and without limitation, an audio coder/decoder (“codec”) and a class D amplifier. In at least one embodiment, SIM card (“SIM”) 1057 may be communicatively coupled to WWAN unit 1056. In at least one embodiment, components such as WLAN unit 1050 and Bluetooth unit 1052, as well as WWAN unit 1056 may be implemented in a Next Generation Form Factor (“NGFF”).

Inference and/or training logic 715 are used to perform inferencing and/or training operations associated with one or more embodiments. Details regarding inference and/or training logic 715 are provided below in conjunction with FIGS. 7A and/or 7B. In at least one embodiment, inference and/or training logic 715 may be used in system FIG. 10 for inferencing or predicting operations based, at least in part, on weight parameters calculated using neural network training operations, neural network functions and/or architectures, or neural network use cases described herein.

Such components can allow for optimizing camera placements for improved user experience.

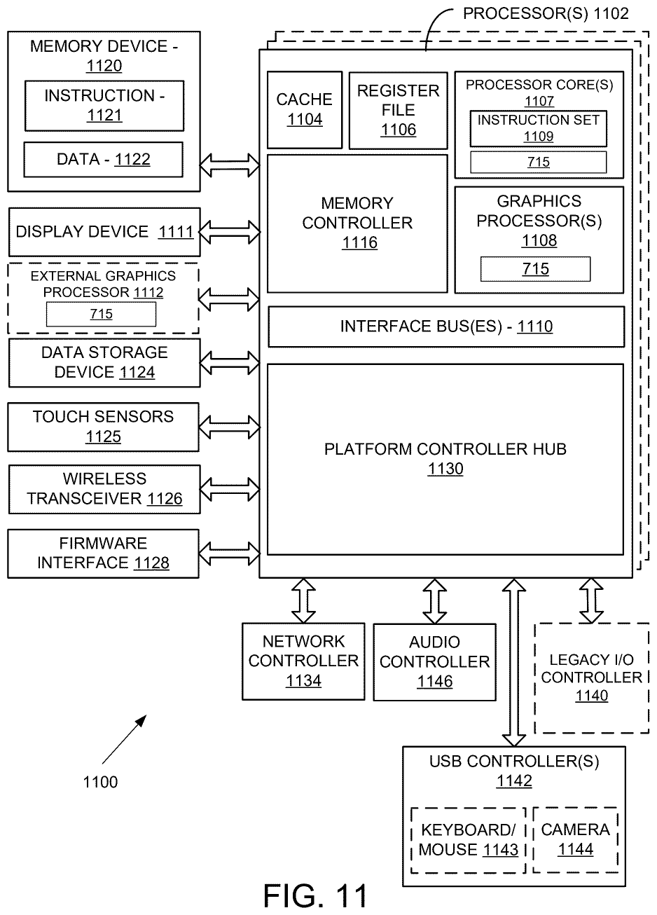

FIG. 11 is a block diagram of a processing system, according to at least one embodiment. In at least one embodiment, system 1100 includes one or more processor(s) 1102 and one or more graphics processor(s) 1108, and may be a single processor desktop system, a multiprocessor workstation system, or a server system having a large number of processor(s) 1102 or processor core(s) 1107. In at least one embodiment, system 1100 is a processing platform incorporated within a system-on-a-chip (SoC) integrated circuit for use in mobile, handheld, or embedded devices.

In at least one embodiment, system 1100 can include, or be incorporated within a server-based gaming platform, a game console, including a game and media console, a mobile gaming console, a handheld game console, or an online game console. In at least one embodiment, system 1100 is a mobile phone, smart phone, tablet computing device or mobile Internet device. In at least one embodiment, processing system 1100 can also include, coupled with, or be integrated within a wearable device, such as a smart watch wearable device, smart eyewear device, augmented reality device, or virtual reality device. In at least one embodiment, processing system 1100 is a television or set top box device having one or more processor(s) 1102 and a graphical interface generated by one or more graphics processor(s) 1108.

In at least one embodiment, one or more processor(s) 1102 each include one or more processor core(s) 1107 to process instructions which, when executed, perform operations for system and user software. In at least one embodiment, each of one or more processor core(s) 1107 is configured to process a specific instruction set 1109. In at least one embodiment, instruction set 1109 may facilitate Complex Instruction Set Computing (CISC), Reduced Instruction Set Computing (RISC), or computing via a Very Long Instruction Word (VLIW). In at least one embodiment, processor core(s) 1107 may each process a different instruction set 1109, which may include instructions to facilitate emulation of other instruction sets. In at least one embodiment, processor core(s) 1107 may also include other processing devices, such a Digital Signal Processor (DSP).

In at least one embodiment, processor(s) 1102 includes cache memory 1104. In at least one embodiment, processor(s) 1102 can have a single internal cache or multiple levels of internal cache. In at least one embodiment, cache memory is shared among various components of processor(s) 1102. In at least one embodiment, processor(s) 1102 also uses an external cache (e.g., a Level-3 (L3) cache or Last Level Cache (LLC)) (not shown), which may be shared among processor core(s) 1107 using known cache coherency techniques. In at least one embodiment, register file 1106 is additionally included in processor(s) 1102 which may include different types of registers for storing different types of data (e.g., integer registers, floating point registers, status registers, and an instruction pointer register). In at least one embodiment, register file 1106 may include general-purpose registers or other registers.

In at least one embodiment, one or more processor(s) 1102 are coupled with one or more interface bus(es) 1110 to transmit communication signals such as address, data, or control signals between processor(s) 1102 and other components in system 1100. In at least one embodiment, interface bus(es) 1110, in one embodiment, can be a processor bus, such as a version of a Direct Media Interface (DMI) bus. In at least one embodiment, interface bus(es) 1110 is not limited to a DMI bus, and may include one or more Peripheral Component Interconnect buses (e.g., PCI, PCI Express), memory busses, or other types of interface busses. In at least one embodiment processor(s) 1102 include an integrated memory controller 1116 and a platform controller hub 1130. In at least one embodiment, memory controller 1116 facilitates communication between a memory device and other components of system 1100, while platform controller hub (PCH) 1130 provides connections to I/O devices via a local I/O bus.

In at least one embodiment, memory device 1120 can be a dynamic random access memory (DRAM) device, a static random access memory (SRAM) device, flash memory device, phase-change memory device, or some other memory device having suitable performance to serve as process memory. In at least one embodiment memory device 1120 can operate as system memory for system 1100, to store data 1122 and instruction 1121 for use when one or more processor(s) 1102 executes an application or process. In at least one embodiment, memory controller 1116 also couples with an optional external graphics processor 1112, which may communicate with one or more graphics processor(s) 1108 in processor(s) 1102 to perform graphics and media operations. In at least one embodiment, a display device 1111 can connect to processor(s) 1102. In at least one embodiment display device 1111 can include one or more of an internal display device, as in a mobile electronic device or a laptop device or an external display device attached via a display interface (e.g., DisplayPort, etc.). In at least one embodiment, display device 1111 can include a head mounted display (HMD) such as a stereoscopic display device for use in virtual reality (VR) applications or augmented reality (AR) applications.

In at least one embodiment, platform controller hub 1130 enables peripherals to connect to memory device 1120 and processor(s) 1102 via a high-speed I/O bus. In at least one embodiment, I/O peripherals include, but are not limited to, an audio controller 1146, a network controller 1134, a firmware interface 1128, a wireless transceiver 1126, touch sensors 1125, a data storage device 1124 (e.g., hard disk drive, flash memory, etc.). In at least one embodiment, data storage device 1124 can connect via a storage interface (e.g., SATA) or via a peripheral bus, such as a Peripheral Component Interconnect bus (e.g., PCI, PCI Express). In at least one embodiment, touch sensors 1125 can include touch screen sensors, pressure sensors, or fingerprint sensors. In at least one embodiment, wireless transceiver 1126 can be a Wi-Fi transceiver, a Bluetooth transceiver, or a mobile network transceiver such as a 3G, 4G, or Long Term Evolution (LTE) transceiver. In at least one embodiment, firmware interface 1128 enables communication with system firmware, and can be, for example, a unified extensible firmware interface (UEFI). In at least one embodiment, network controller 1134 can enable a network connection to a wired network. In at least one embodiment, a high-performance network controller (not shown) couples with interface bus(es) 1110. In at least one embodiment, audio controller 1146 is a multi-channel high definition audio controller. In at least one embodiment, system 1100 includes an optional legacy I/O controller 1140 for coupling legacy (e.g., Personal System 2 (PS/2)) devices to system. In at least one embodiment, platform controller hub 1130 can also connect to one or more Universal Serial Bus (USB) controller(s) 1142 connect input devices, such as keyboard and mouse 1143 combinations, a camera 1144, or other USB input devices.

In at least one embodiment, an instance of memory controller 1116 and platform controller hub 1130 may be integrated into a discreet external graphics processor, such as external graphics processor 1112. In at least one embodiment, platform controller hub 1130 and/or memory controller 1116 may be external to one or more processor(s) 1102. For example, in at least one embodiment, system 1100 can include an external memory controller 1116 and platform controller hub 1130, which may be configured as a memory controller hub and peripheral controller hub within a system chipset that is in communication with processor(s) 1102.

Inference and/or training logic 715 are used to perform inferencing and/or training operations associated with one or more embodiments. Details regarding inference and/or training logic 715 are provided below in conjunction with FIGS. 7A and/or 7B. In at least one embodiment portions or all of inference and/or training logic 715 may be incorporated into graphics processor 1500. For example, in at least one embodiment, training and/or inferencing techniques described herein may use one or more of ALUs embodied in a graphics processor. Moreover, in at least one embodiment, inferencing and/or training operations described herein may be done using logic other than logic illustrated in FIGS. 7A and/or 7B. In at least one embodiment, weight parameters may be stored in on-chip or off-chip memory and/or registers (shown or not shown) that configure ALUs of a graphics processor to perform one or more machine learning algorithms, neural network architectures, use cases, or training techniques described herein.

Such components can allow for optimizing camera placements for improved user experience.

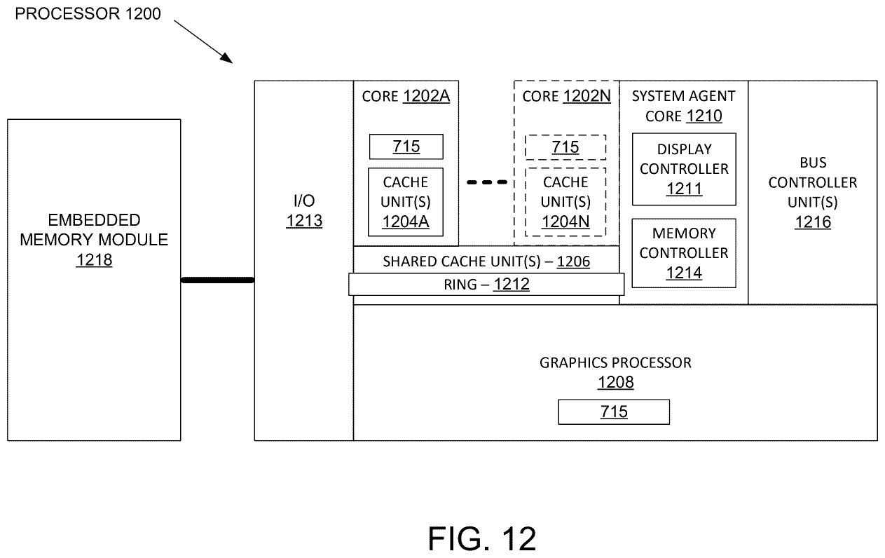

FIG. 12 is a block diagram of a processor 1200 having one or more processor core(s) 1202A-1202N, an integrated memory controller 1214, and an integrated graphics processor 1208, according to at least one embodiment. In at least one embodiment, processor 1200 can include additional cores up to and including additional core 1202N represented by dashed lined boxes. In at least one embodiment, each of processor core(s) 1202A-1202N includes one or more internal cache unit(s) 1204A-1204N. In at least one embodiment, each processor core also has access to one or more shared cached unit(s) 1206.

In at least one embodiment, internal cache unit(s) 1204A-1204N and shared cache unit(s) 1206 represent a cache memory hierarchy within processor 1200. In at least one embodiment, cache unit(s) 1204A-1204N may include at least one level of instruction and data cache within each processor core and one or more levels of shared mid-level cache, such as a Level 2 (L2), Level 3 (L3), Level 4 (L4), or other levels of cache, where a highest level of cache before external memory is classified as an LLC. In at least one embodiment, cache coherency logic maintains coherency between various cache unit(s) 1206 and 1204A-1204N.

In at least one embodiment, processor 1200 may also include a set of one or more bus controller unit(s) 1216 and a system agent core 1210. In at least one embodiment, one or more bus controller unit(s) 1216 manage a set of peripheral buses, such as one or more PCI or PCI express busses. In at least one embodiment, system agent core 1210 provides management functionality for various processor components. In at least one embodiment, system agent core 1210 includes one or more integrated memory controllers 1214 to manage access to various external memory devices (not shown).

In at least one embodiment, one or more of processor core(s) 1202A-1202N include support for simultaneous multi-threading. In at least one embodiment, system agent core 1210 includes components for coordinating and processor core(s) 1202A-1202N during multi-threaded processing. In at least one embodiment, system agent core 1210 may additionally include a power control unit (PCU), which includes logic and components to regulate one or more power states of processor core(s) 1202A-1202N and graphics processor 1208.

In at least one embodiment, processor 1200 additionally includes graphics processor 1208 to execute graphics processing operations. In at least one embodiment, graphics processor 1208 couples with shared cache unit(s) 1206, and system agent core 1210, including one or more integrated memory controllers 1214. In at least one embodiment, system agent core 1210 also includes a display controller 1211 to drive graphics processor output to one or more coupled displays. In at least one embodiment, display controller 1211 may also be a separate module coupled with graphics processor 1208 via at least one interconnect, or may be integrated within graphics processor 1208.

In at least one embodiment, a ring based interconnect unit 1212 is used to couple internal components of processor 1200. In at least one embodiment, an alternative interconnect unit may be used, such as a point-to-point interconnect, a switched interconnect, or other techniques. In at least one embodiment, graphics processor 1208 couples with a ring based interconnect unit 1212 via an I/O link 1213.

In at least one embodiment, I/O link 1213 represents at least one of multiple varieties of I/O interconnects, including an on package I/O interconnect which facilitates communication between various processor components and a high-performance embedded memory module 1218, such as an eDRAM module. In at least one embodiment, each of processor core(s) 1202A-1202N and graphics processor 1208 use embedded memory modules 1218 as a shared Last Level Cache.

In at least one embodiment, processor core(s) 1202A-1202N are homogenous cores executing a common instruction set architecture. In at least one embodiment, processor core(s) 1202A-1202N are heterogeneous in terms of instruction set architecture (ISA), where one or more of processor core(s) 1202A-1202N execute a common instruction set, while one or more other cores of processor core(s) 1202A-1202N executes a subset of a common instruction set or a different instruction set. In at least one embodiment, processor core(s) 1202A-1202N are heterogeneous in terms of microarchitecture, where one or more cores having a relatively higher power consumption couple with one or more power cores having a lower power consumption. In at least one embodiment, processor 1200 can be implemented on one or more chips or as an SoC integrated circuit.

Inference and/or training logic 715 are used to perform inferencing and/or training operations associated with one or more embodiments. Details regarding inference and/or training logic 715 are provided below in conjunction with FIGS. 7A and/or 7B. In at least one embodiment portions or all of inference and/or training logic 715 may be incorporated into processor 1200. For example, in at least one embodiment, training and/or inferencing techniques described herein may use one or more of ALUs embodied in graphics processor 1208, graphics core(s) 1202A-1202N, or other components in FIG. 12. Moreover, in at least one embodiment, inferencing and/or training operations described herein may be done using logic other than logic illustrated in FIGS. 7A and/or 7B. In at least one embodiment, weight parameters may be stored in on-chip or off-chip memory and/or registers (shown or not shown) that configure ALUs of graphics processor 1200 to perform one or more machine learning algorithms, neural network architectures, use cases, or training techniques described herein.

Such components can allow for optimizing camera placements for improved user experience.

### Virtualized Computing Platform

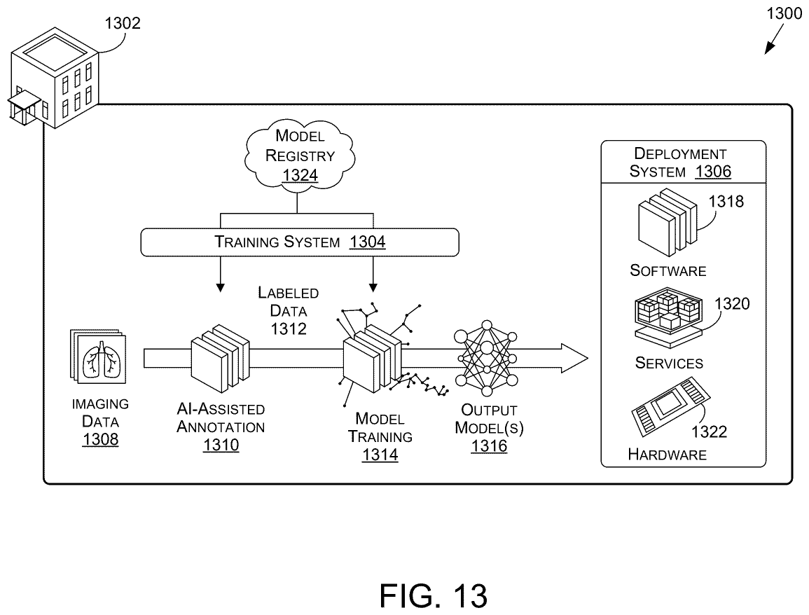

FIG. 13 is an example data flow diagram for a process 1300 of generating and deploying an image processing and inferencing pipeline, in accordance with at least one embodiment. In at least one embodiment, process 1300 may be deployed for use with imaging devices, processing devices, and/or other device types at one or more facilities 1302. Process 1300 may be executed within a training system 1304 and/or a deployment system 1306. In at least one embodiment, training system 1304 may be used to perform training, deployment, and implementation of machine learning models (e.g., neural networks, object detection algorithms, computer vision algorithms, etc.) for use in deployment system 1306. In at least one embodiment, deployment system 1306 may be configured to offload processing and compute resources among a distributed computing environment to reduce infrastructure requirements at facility 1302. In at least one embodiment, one or more applications in a pipeline may use or call upon services (e.g., inference, visualization, compute, AI, etc.) of deployment system 1306 during execution of applications.

In at least one embodiment, some of applications used in advanced processing and inferencing pipelines may use machine learning models or other AI to perform one or more processing steps. In at least one embodiment, machine learning models may be trained at facility 1302 using data 1308 (such as imaging data) generated at facility 1302 (and stored on one or more picture archiving and communication system (PACS) servers at facility 1302), may be trained using imaging or sequencing data 1308 from another facility(ies), or a combination thereof. In at least one embodiment, training system 1304 may be used to provide applications, services, and/or other resources for generating working, deployable machine learning models for deployment system 1306.

In at least one embodiment, model registry 1324 may be backed by object storage that may support versioning and object metadata. In at least one embodiment, object storage may be accessible through, for example, a cloud storage compatible application programming interface (API) from within a cloud platform. In at least one embodiment, machine learning models within model registry 1324 may uploaded, listed, modified, or deleted by developers or partners of a system interacting with an API. In at least one embodiment, an API may provide access to methods that allow users with appropriate credentials to associate models with applications, such that models may be executed as part of execution of containerized instantiations of applications.

In at least one embodiment, training system 1304 (FIG. 13) may include a scenario where facility 1302 is training their own machine learning model, or has an existing machine learning model that needs to be optimized or updated. In at least one embodiment, imaging data 1308 generated by imaging device(s), sequencing devices, and/or other device types may be received. In at least one embodiment, once imaging data 1308 is received, AI-assisted annotation 1310 may be used to aid in generating annotations corresponding to imaging data 1308 to be used as ground truth data for a machine learning model. In at least one embodiment, AI-assisted annotation 1310 may include one or more machine learning models (e.g., convolutional neural networks (CNNs)) that may be trained to generate annotations corresponding to certain types of imaging data 1308 (e.g., from certain devices). In at least one embodiment, AI-assisted annotation 1310 may then be used directly, or may be adjusted or fine-tuned using an annotation tool to generate ground truth data. In at least one embodiment, AI-assisted annotation 1310, labeled data 1312, or a combination thereof may be used as ground truth data for training a machine learning model. In at least one embodiment, a trained machine learning model may be referred to as output model(s) 1316, and may be used by deployment system 1306, as described herein.

In at least one embodiment, a training pipeline may include a scenario where facility 1302 needs a machine learning model for use in performing one or more processing tasks for one or more applications in deployment system 1306, but facility 1302 may not currently have such a machine learning model (or may not have a model that is optimized, efficient, or effective for such purposes). In at least one embodiment, an existing machine learning model may be selected from a model registry 1324. In at least one embodiment, model registry 1324 may include machine learning models trained to perform a variety of different inference tasks on imaging data. In at least one embodiment, machine learning models in model registry 1324 may have been trained on imaging data from different facilities than facility 1302 (e.g., facilities remotely located). In at least one embodiment, machine learning models may have been trained on imaging data from one location, two locations, or any number of locations. In at least one embodiment, when being trained on imaging data from a specific location, training may take place at that location, or at least in a manner that protects confidentiality of imaging data or restricts imaging data from being transferred off-premises. In at least one embodiment, once a model is trained—or partially trained—at one location, a machine learning model may be added to model registry 1324. In at least one embodiment, a machine learning model may then be retrained, or updated, at any number of other facilities, and a retrained or updated model may be made available in model registry 1324. In at least one embodiment, a machine learning model may then be selected from model registry 1324—and referred to as output model(s) 1316—and may be used in deployment system 1306 to perform one or more processing tasks for one or more applications of a deployment system.

In at least one embodiment, a scenario may include facility 1302 requiring a machine learning model for use in performing one or more processing tasks for one or more applications in deployment system 1306, but facility 1302 may not currently have such a machine learning model (or may not have a model that is optimized, efficient, or effective for such purposes). In at least one embodiment, a machine learning model selected from model registry 1324 may not be fine-tuned or optimized for imaging data 1308 generated at facility 1302 because of differences in populations, robustness of training data used to train a machine learning model, diversity in anomalies of training data, and/or other issues with training data. In at least one embodiment, AI-assisted annotation 1310 may be used to aid in generating annotations corresponding to imaging data 1308 to be used as ground truth data for retraining or updating a machine learning model. In at least one embodiment, labeled data 1312 may be used as ground truth data for training a machine learning model. In at least one embodiment, retraining or updating a machine learning model may be referred to as model training 1314. In at least one embodiment, model training 1314—e.g., AI-assisted annotation 1310, labeled data 1312, or a combination thereof—may be used as ground truth data for retraining or updating a machine learning model. In at least one embodiment, a trained machine learning model may be referred to as output model(s) 1316, and may be used by deployment system 1306, as described herein.

In at least one embodiment, deployment system 1306 may include software 1318, services 1320, hardware 1322, and/or other components, features, and functionality. In at least one embodiment, deployment system 1306 may include a software “stack,” such that software 1318 may be built on top of services 1320 and may use services 1320 to perform some or all of processing tasks, and services 1320 and software 1318 may be built on top of hardware 1322 and use hardware 1322 to execute processing, storage, and/or other compute tasks of deployment system 1306. In at least one embodiment, software 1318 may include any number of different containers, where each container may execute an instantiation of an application. In at least one embodiment, each application may perform one or more processing tasks in an advanced processing and inferencing pipeline (e.g., inferencing, object detection, feature detection, segmentation, image enhancement, calibration, etc.). In at least one embodiment, an advanced processing and inferencing pipeline may be defined based on selections of different containers that are desired or required for processing imaging data 1308, in addition to containers that receive and configure imaging data for use by each container and/or for use by facility 1302 after processing through a pipeline (e.g., to convert outputs back to a usable data type). In at least one embodiment, a combination of containers within software 1318 (e.g., that make up a pipeline) may be referred to as a virtual instrument (as described in more detail herein), and a virtual instrument may leverage services 1320 and hardware 1322 to execute some or all processing tasks of applications instantiated in containers.

In at least one embodiment, a data processing pipeline may receive input data (e.g., imaging data 1308) in a specific format in response to an inference request (e.g., a request from a user of deployment system 1306). In at least one embodiment, input data may be representative of one or more images, video, and/or other data representations generated by one or more imaging devices. In at least one embodiment, data may undergo pre-processing as part of data processing pipeline to prepare data for processing by one or more applications. In at least one embodiment, post-processing may be performed on an output of one or more inferencing tasks or other processing tasks of a pipeline to prepare an output data for a next application and/or to prepare output data for transmission and/or use by a user (e.g., as a response to an inference request). In at least one embodiment, inferencing tasks may be performed by one or more machine learning models, such as trained or deployed neural networks, which may include output model(s) 1316 of training system 1304.

In at least one embodiment, tasks of data processing pipeline may be encapsulated in a container(s) that each represents a discrete, fully functional instantiation of an application and virtualized computing environment that is able to reference machine learning models. In at least one embodiment, containers or applications may be published into a private (e.g., limited access) area of a container registry (described in more detail herein), and trained or deployed models may be stored in model registry 1324 and associated with one or more applications. In at least one embodiment, images of applications (e.g., container images) may be available in a container registry, and once selected by a user from a container registry for deployment in a pipeline, an image may be used to generate a container for an instantiation of an application for use by a user's system.

In at least one embodiment, developers (e.g., software developers, clinicians, doctors, etc.) may develop, publish, and store applications (e.g., as containers) for performing image processing and/or inferencing on supplied data. In at least one embodiment, development, publishing, and/or storing may be performed using a software development kit (SDK) associated with a system (e.g., to ensure that an application and/or container developed is compliant with or compatible with a system). In at least one embodiment, an application that is developed may be tested locally (e.g., at a first facility, on data from a first facility) with an SDK which may support at least some of services 1320 as a system (e.g., system 1200 of FIG. 12). In at least one embodiment, because DICOM objects may contain anywhere from one to hundreds of images or other data types, and due to a variation in data, a developer may be responsible for managing (e.g., setting constructs for, building pre-processing into an application, etc.) extraction and preparation of incoming data. In at least one embodiment, once validated by process 1300 (e.g., for accuracy), an application may be available in a container registry for selection and/or implementation by a user to perform one or more processing tasks with respect to data at a facility (e.g., a second facility) of a user.

In at least one embodiment, developers may then share applications or containers through a network for access and use by users of a system (e.g., system 1300 of FIG. 13). In at least one embodiment, completed and validated applications or containers may be stored in a container registry and associated machine learning models may be stored in model registry 1324. In at least one embodiment, a requesting entity—who provides an inference or image processing request—may browse a container registry and/or model registry 1324 for an application, container, dataset, machine learning model, etc., select a desired combination of elements for inclusion in data processing pipeline, and submit an imaging processing request. In at least one embodiment, a request may include input data (and associated patient data, in some examples) that is necessary to perform a request, and/or may include a selection of application(s) and/or machine learning models to be executed in processing a request. In at least one embodiment, a request may then be passed to one or more components of deployment system 1306 (e.g., a cloud) to perform processing of data processing pipeline. In at least one embodiment, processing by deployment system 1306 may include referencing selected elements (e.g., applications, containers, models, etc.) from a container registry and/or model registry 1324. In at least one embodiment, once results are generated by a pipeline, results may be returned to a user for reference (e.g., for viewing in a viewing application suite executing on a local, on-premises workstation or terminal).

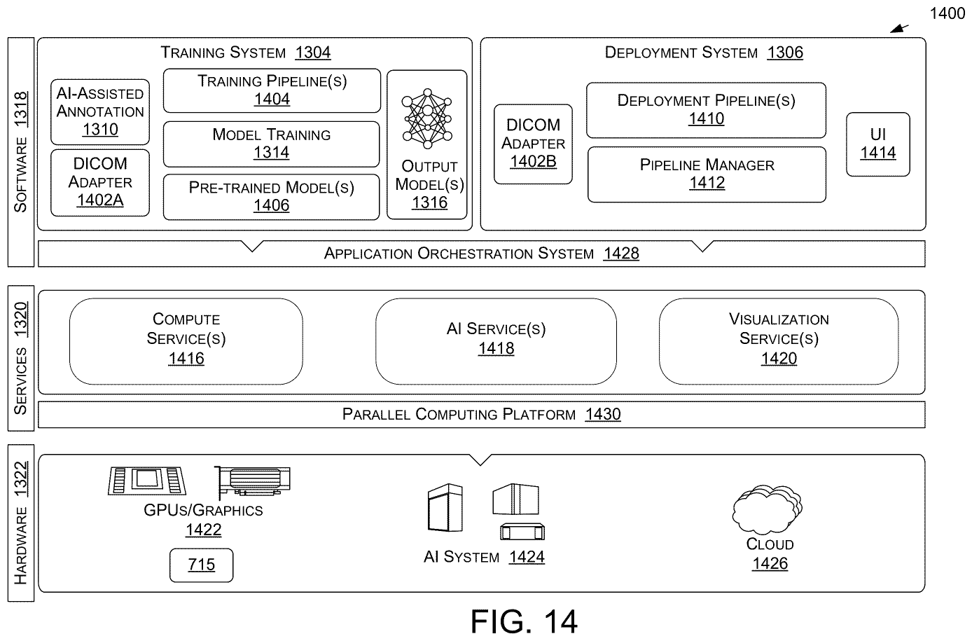

In at least one embodiment, to aid in processing or execution of applications or containers in pipelines, services 1320 may be leveraged. In at least one embodiment, services 1320 may include compute services, artificial intelligence (AI) services, visualization services, and/or other service types. In at least one embodiment, services 1320 may provide functionality that is common to one or more applications in software 1318, so functionality may be abstracted to a service that may be called upon or leveraged by applications. In at least one embodiment, functionality provided by services 1320 may run dynamically and more efficiently, while also scaling well by allowing applications to process data in parallel (e.g., using a parallel computing platform 1430 (FIG. 14)). In at least one embodiment, rather than each application that shares a same functionality offered by services 1320 being required to have a respective instance of services 1320, services 1320 may be shared between and among various applications. In at least one embodiment, services may include an inference server or engine that may be used for executing detection or segmentation tasks, as non-limiting examples. In at least one embodiment, a model training service may be included that may provide machine learning model training and/or retraining capabilities. In at least one embodiment, a data augmentation service may further be included that may provide GPU accelerated data (e.g., DICOM, RIS, CIS, REST compliant, RPC, raw, etc.) extraction, resizing, scaling, and/or other augmentation. In at least one embodiment, a visualization service may be used that may add image rendering effects—such as ray-tracing, rasterization, denoising, sharpening, etc.—to add realism to two-dimensional (2D) and/or three-dimensional (3D) models. In at least one embodiment, virtual instrument services may be included that provide for beam-forming, segmentation, inferencing, imaging, and/or support for other applications within pipelines of virtual instruments.

In at least one embodiment, where services 1320 includes an AI service (e.g., an inference service), one or more machine learning models may be executed by calling upon (e.g., as an API call) an inference service (e.g., an inference server) to execute machine learning model(s), or processing thereof, as part of application execution. In at least one embodiment, where another application includes one or more machine learning models for segmentation tasks, an application may call upon an inference service to execute machine learning models for performing one or more of processing operations associated with segmentation tasks. In at least one embodiment, software 1318 implementing advanced processing and inferencing pipeline that includes segmentation application and anomaly detection application may be streamlined because each application may call upon a same inference service to perform one or more inferencing tasks.

In at least one embodiment, hardware 1322 may include GPUs, CPUs, graphics cards, an AI/deep learning system (e.g., an AI supercomputer, such as NVIDIA's DGX), a cloud platform, or a combination thereof. In at least one embodiment, different types of hardware 1322 may be used to provide efficient, purpose-built support for software 1318 and services 1320 in deployment system 1306. In at least one embodiment, use of GPU processing may be implemented for processing locally (e.g., at facility 1302), within an AI/deep learning system, in a cloud system, and/or in other processing components of deployment system 1306 to improve efficiency, accuracy, and efficacy of image processing and generation. In at least one embodiment, software 1318 and/or services 1320 may be optimized for GPU processing with respect to deep learning, machine learning, and/or high-performance computing, as non-limiting examples. In at least one embodiment, at least some of computing environment of deployment system 1306 and/or training system 1304 may be executed in a datacenter one or more supercomputers or high performance computing systems, with GPU optimized software (e.g., hardware and software combination of NVIDIA's DGX System). In at least one embodiment, hardware 1322 may include any number of GPUs that may be called upon to perform processing of data in parallel, as described herein. In at least one embodiment, cloud platform may further include GPU processing for GPU-optimized execution of deep learning tasks, machine learning tasks, or other computing tasks. In at least one embodiment, cloud platform (e.g., NVIDIA's NGC) may be executed using an AI/deep learning supercomputer(s) and/or GPU-optimized software (e.g., as provided on NVIDIA's DGX Systems) as a hardware abstraction and scaling platform. In at least one embodiment, cloud platform may integrate an application container clustering system or orchestration system (e.g., KUBERNETES) on multiple GPUs to enable seamless scaling and load balancing.

FIG. 14 is a system diagram for an example system 1400 for generating and deploying an imaging deployment pipeline, in accordance with at least one embodiment. In at least one embodiment, system 1400 may be used to implement process 1300 of FIG. 13 and/or other processes including advanced processing and inferencing pipelines. In at least one embodiment, system 1400 may include training system 1304 and deployment system 1306. In at least one embodiment, training system 1304 and deployment system 1306 may be implemented using software 1318, services 1320, and/or hardware 1322, as described herein.

In at least one embodiment, system 1400 (e.g., training system 1304 and/or deployment system 1306) may implemented in a cloud computing environment (e.g., using cloud 1426). In at least one embodiment, system 1400 may be implemented locally with respect to a healthcare services facility, or as a combination of both cloud and local computing resources. In at least one embodiment, access to APIs in cloud 1426 may be restricted to authorized users through enacted security measures or protocols. In at least one embodiment, a security protocol may include web tokens that may be signed by an authentication (e.g., AuthN, AuthZ, Gluecon, etc.) service and may carry appropriate authorization. In at least one embodiment, APIs of virtual instruments (described herein), or other instantiations of system 1400, may be restricted to a set of public IPs that have been vetted or authorized for interaction.

In at least one embodiment, various components of system 1400 may communicate between and among one another using any of a variety of different network types, including but not limited to local area networks (LANs) and/or wide area networks (WANs) via wired and/or wireless communication protocols. In at least one embodiment, communication between facilities and components of system 1400 (e.g., for transmitting inference requests, for receiving results of inference requests, etc.) may be communicated over data bus(ses), wireless data protocols (Wi-Fi), wired data protocols (e.g., Ethernet), etc.

In at least one embodiment, training system 1304 may execute training pipelines 1404, similar to those described herein with respect to FIG. 13. In at least one embodiment, where one or more machine learning models are to be used in deployment pipeline(s) 1410 by deployment system 1306, training pipelines 1404 may be used to train or retrain one or more (e.g. pre-trained) models, and/or implement one or more of pre-trained models 1406 (e.g., without a need for retraining or updating). In at least one embodiment, as a result of training pipelines 1404, output model(s) 1316 may be generated. In at least one embodiment, training pipelines 1404 may include any number of processing steps, such as but not limited to imaging data (or other input data) conversion or adaption In at least one embodiment, for different machine learning models used by deployment system 1306, different training pipelines 1404 may be used. In at least one embodiment, training pipeline 1404 similar to a first example described with respect to FIG. 13 may be used for a first machine learning model, training pipeline 1404 similar to a second example described with respect to FIG. 13 may be used for a second machine learning model, and training pipeline 1404 similar to a third example described with respect to FIG. 13 may be used for a third machine learning model. In at least one embodiment, any combination of tasks within training system 1304 may be used depending on what is required for each respective machine learning model. In at least one embodiment, one or more of machine learning models may already be trained and ready for deployment so machine learning models may not undergo any processing by training system 1304, and may be implemented by deployment system 1306.

In at least one embodiment, output model(s) 1316 and/or pre-trained models 1406 may include any types of machine learning models depending on implementation or embodiment. In at least one embodiment, and without limitation, machine learning models used by system 1400 may include machine learning model(s) using linear regression, logistic regression, decision trees, support vector machines (SVM), Naïve Bayes, k-nearest neighbor (Knn), K means clustering, random forest, dimensionality reduction algorithms, gradient boosting algorithms, neural networks (e.g., auto-encoders, convolutional, recurrent, perceptrons, Long/Short Term Memory (LSTM), Hopfield, Boltzmann, deep belief, deconvolutional, generative adversarial, liquid state machine, etc.), and/or other types of machine learning models.

In at least one embodiment, training pipelines 1404 may include AI-assisted annotation, as described in more detail herein with respect to at least FIG. 14. In at least one embodiment, labeled data 1312 (e.g., traditional annotation) may be generated by any number of techniques. In at least one embodiment, labels or other annotations may be generated within a drawing program (e.g., an annotation program), a computer aided design (CAD) program, a labeling program, another type of program suitable for generating annotations or labels for ground truth, and/or may be hand drawn, in some examples. In at least one embodiment, ground truth data may be synthetically produced (e.g., generated from computer models or renderings), real produced (e.g., designed and produced from real-world data), machine-automated (e.g., using feature analysis and learning to extract features from data and then generate labels), human annotated (e.g., labeler, or annotation expert, defines location of labels), and/or a combination thereof. In at least one embodiment, for each instance of imaging data 1308 (or other data type used by machine learning models), there may be corresponding ground truth data generated by training system 1304. In at least one embodiment, AI-assisted annotation may be performed as part of deployment pipeline(s) 1410; either in addition to, or in lieu of AI-assisted annotation included in training pipelines 1404. In at least one embodiment, system 1400 may include a multi-layer platform that may include a software layer (e.g., software 1318) of diagnostic applications (or other application types) that may perform one or more medical imaging and diagnostic functions. In at least one embodiment, system 1400 may be communicatively coupled to (e.g., via encrypted links) PACS server networks of one or more facilities. In at least one embodiment, system 1400 may be configured to access and referenced data from PACS servers to perform operations, such as training machine learning models, deploying machine learning models, image processing, inferencing, and/or other operations.

In at least one embodiment, a software layer may be implemented as a secure, encrypted, and/or authenticated API through which applications or containers may be invoked (e.g., called) from an external environment(s) (e.g., facility 1302). In at least one embodiment, applications may then call or execute one or more services 1320 for performing compute, AI, or visualization tasks associated with respective applications, and software 1318 and/or services 1320 may leverage hardware 1322 to perform processing tasks in an effective and efficient manner. In at least one embodiment, communications sent to, or received by, a training system 1304 and a deployment system 1306 may occur using a pair of DICOM adapters 1402A, 1402B.

In at least one embodiment, deployment system 1306 may execute deployment pipeline(s) 1410. In at least one embodiment, deployment pipeline(s) 1410 may include any number of applications that may be sequentially, non-sequentially, or otherwise applied to imaging data (and/or other data types) generated by imaging devices, sequencing devices, genomics devices, etc.-including AI-assisted annotation, as described above. In at least one embodiment, as described herein, a deployment pipeline(s) 1410 for an individual device may be referred to as a virtual instrument for a device (e.g., a virtual ultrasound instrument, a virtual CT scan instrument, a virtual sequencing instrument, etc.). In at least one embodiment, for a single device, there may be more than one deployment pipeline(s) 1410 depending on information desired from data generated by a device. In at least one embodiment, where detections of anomalies are desired from an MRI machine, there may be a first deployment pipeline(s) 1410, and where image enhancement is desired from output of an MRI machine, there may be a second deployment pipeline(s) 1410.

In at least one embodiment, an image generation application may include a processing task that includes use of a machine learning model. In at least one embodiment, a user may desire to use their own machine learning model, or to select a machine learning model from model registry 1324. In at least one embodiment, a user may implement their own machine learning model or select a machine learning model for inclusion in an application for performing a processing task. In at least one embodiment, applications may be selectable and customizable, and by defining constructs of applications, deployment and implementation of applications for a particular user are presented as a more seamless user experience. In at least one embodiment, by leveraging other features of system 1400—such as services 1320 and hardware 1322—deployment pipeline(s) 1410 may be even more user friendly, provide for easier integration, and produce more accurate, efficient, and timely results.

In at least one embodiment, deployment system 1306 may include a user interface (“UI”) 1414 (e.g., a graphical user interface, a web interface, etc.) that may be used to select applications for inclusion in deployment pipeline(s) 1410, arrange applications, modify or change applications or parameters or constructs thereof, use and interact with deployment pipeline(s) 1410 during set-up and/or deployment, and/or to otherwise interact with deployment system 1306. In at least one embodiment, although not illustrated with respect to training system 1304, UI 1414 (or a different user interface) may be used for selecting models for use in deployment system 1306, for selecting models for training, or retraining, in training system 1304, and/or for otherwise interacting with training system 1304.

In at least one embodiment, pipeline manager 1412 may be used, in addition to an application orchestration system 1428, to manage interaction between applications or containers of deployment pipeline(s) 1410 and services 1320 and/or hardware 1322. In at least one embodiment, pipeline manager 1412 may be configured to facilitate interactions from application to application, from application to services 1320, and/or from application or service to hardware 1322. In at least one embodiment, although illustrated as included in software 1318, this is not intended to be limiting, and in some examples pipeline manager 1412 may be included in services 1320. In at least one embodiment, application orchestration system 1428 (e.g., Kubernetes, DOCKER, etc.) may include a container orchestration system that may group applications into containers as logical units for coordination, management, scaling, and deployment. In at least one embodiment, by associating applications from deployment pipeline(s) 1410 (e.g., a reconstruction application, a segmentation application, etc.) with individual containers, each application may execute in a self-contained environment (e.g., at a kernel level) to increase speed and efficiency.

In at least one embodiment, each application and/or container (or image thereof) may be individually developed, modified, and deployed (e.g., a first user or developer may develop, modify, and deploy a first application and a second user or developer may develop, modify, and deploy a second application separate from a first user or developer), which may allow for focus on, and attention to, a task of a single application and/or container(s) without being hindered by tasks of another application(s) or container(s). In at least one embodiment, communication, and cooperation between different containers or applications may be aided by pipeline manager 1412 and application orchestration system 1428. In at least one embodiment, so long as an expected input and/or output of each container or application is known by a system (e.g., based on constructs of applications or containers), application orchestration system 1428 and/or pipeline manager 1412 may facilitate communication among and between, and sharing of resources among and between, each of applications or containers. In at least one embodiment, because one or more of applications or containers in deployment pipeline(s) 1410 may share same services and resources, application orchestration system 1428 may orchestrate, load balance, and determine sharing of services or resources between and among various applications or containers. In at least one embodiment, a scheduler may be used to track resource requirements of applications or containers, current usage or planned usage of these resources, and resource availability. In at least one embodiment, a scheduler may thus allocate resources to different applications and distribute resources between and among applications in view of requirements and availability of a system. In some examples, a scheduler (and/or other component of application orchestration system 1428) may determine resource availability and distribution based on constraints imposed on a system (e.g., user constraints), such as quality of service (QoS), urgency of need for data outputs (e.g., to determine whether to execute real-time processing or delayed processing), etc.

In at least one embodiment, services 1320 leveraged by and shared by applications or containers in deployment system 1306 may include compute service(s) 1416, AI service(s) 1418, visualization service(s) 1420, and/or other service types. In at least one embodiment, applications may call (e.g., execute) one or more of services 1320 to perform processing operations for an application. In at least one embodiment, compute service(s) 1416 may be leveraged by applications to perform super-computing or other high-performance computing (HPC) tasks. In at least one embodiment, compute service(s) 1416 may be leveraged to perform parallel processing (e.g., using a parallel computing platform 1430) for processing data through one or more of applications and/or one or more tasks of a single application, substantially simultaneously. In at least one embodiment, parallel computing platform 1430 (e.g., NVIDIA's CUDA) may enable general purpose computing on GPUs (GPGPU) (e.g., GPUs/Graphics 1422). In at least one embodiment, a software layer of parallel computing platform 1430 may provide access to virtual instruction sets and parallel computational elements of GPUs, for execution of compute kernels. In at least one embodiment, parallel computing platform 1430 may include memory and, in some embodiments, a memory may be shared between and among multiple containers, and/or between and among different processing tasks within a single container. In at least one embodiment, inter-process communication (IPC) calls may be generated for multiple containers and/or for multiple processes within a container to use same data from a shared segment of memory of parallel computing platform 1430 (e.g., where multiple different stages of an application or multiple applications are processing same information). In at least one embodiment, rather than making a copy of data and moving data to different locations in memory (e.g., a read/write operation), same data in same location of a memory may be used for any number of processing tasks (e.g., at a same time, at different times, etc.). In at least one embodiment, as data is used to generate new data as a result of processing, this information of a new location of data may be stored and shared between various applications. In at least one embodiment, location of data and a location of updated or modified data may be part of a definition of how a payload is understood within containers.

In at least one embodiment, AI service(s) 1418 may be leveraged to perform inferencing services for executing machine learning model(s) associated with applications (e.g., tasked with performing one or more processing tasks of an application). In at least one embodiment, AI service(s) 1418 may leverage AI system 1424 to execute machine learning model(s) (e.g., neural networks, such as CNNs) for segmentation, reconstruction, object detection, feature detection, classification, and/or other inferencing tasks. In at least one embodiment, applications of deployment pipeline(s) 1410 may use one or more of output model(s) 1316 from training system 1304 and/or other models of applications to perform inference on imaging data. In at least one embodiment, two or more examples of inferencing using application orchestration system 1428 (e.g., a scheduler) may be available. In at least one embodiment, a first category may include a high priority/low latency path that may achieve higher service level agreements, such as for performing inference on urgent requests during an emergency, or for a radiologist during diagnosis. In at least one embodiment, a second category may include a standard priority path that may be used for requests that may be non-urgent or where analysis may be performed at a later time. In at least one embodiment, application orchestration system 1428 may distribute resources (e.g., services 1320 and/or hardware 1322) based on priority paths for different inferencing tasks of AI service(s) 1418.

In at least one embodiment, shared storage may be mounted to AI service(s) 1418 within system 1400. In at least one embodiment, shared storage may operate as a cache (or other storage device type) and may be used to process inference requests from applications. In at least one embodiment, when an inference request is submitted, a request may be received by a set of API instances of deployment system 1306, and one or more instances may be selected (e.g., for best fit, for load balancing, etc.) to process a request. In at least one embodiment, to process a request, a request may be entered into a database, a machine learning model may be located from model registry 1324 if not already in a cache, a validation step may ensure appropriate machine learning model is loaded into a cache (e.g., shared storage), and/or a copy of a model may be saved to a cache. In at least one embodiment, a scheduler (e.g., of pipeline manager 1412) may be used to launch an application that is referenced in a request if an application is not already running or if there are not enough instances of an application. In at least one embodiment, if an inference server is not already launched to execute a model, an inference server may be launched. Any number of inference servers may be launched per model. In at least one embodiment, in a pull model, in which inference servers are clustered, models may be cached whenever load balancing is advantageous. In at least one embodiment, inference servers may be statically loaded in corresponding, distributed servers.

In at least one embodiment, inferencing may be performed using an inference server that runs in a container. In at least one embodiment, an instance of an inference server may be associated with a model (and optionally a plurality of versions of a model). In at least one embodiment, if an instance of an inference server does not exist when a request to perform inference on a model is received, a new instance may be loaded. In at least one embodiment, when starting an inference server, a model may be passed to an inference server such that a same container may be used to serve different models so long as inference server is running as a different instance.

In at least one embodiment, during application execution, an inference request for a given application may be received, and a container (e.g., hosting an instance of an inference server) may be loaded (if not already), and a start procedure may be called. In at least one embodiment, pre-processing logic in a container may load, decode, and/or perform any additional pre-processing on incoming data (e.g., using a CPU(s) and/or GPU(s)). In at least one embodiment, once data is prepared for inference, a container may perform inference as necessary on data. In at least one embodiment, this may include a single inference call on one image (e.g., a hand X-ray), or may require inference on hundreds of images (e.g., a chest CT). In at least one embodiment, an application may summarize results before completing, which may include, without limitation, a single confidence score, pixel level-segmentation, voxel-level segmentation, generating a visualization, or generating text to summarize findings. In at least one embodiment, different models or applications may be assigned different priorities. For example, some models may have a real-time (TAT<1 min) priority while others may have lower priority (e.g., TAT<10 min). In at least one embodiment, model execution times may be measured from requesting institution or entity and may include partner network traversal time, as well as execution on an inference service.

In at least one embodiment, transfer of requests between services 1320 and inference applications may be hidden behind a software development kit (SDK), and robust transport may be provide through a queue. In at least one embodiment, a request will be placed in a queue via an API for an individual application/tenant ID combination and an SDK will pull a request from a queue and give a request to an application. In at least one embodiment, a name of a queue may be provided in an environment from where an SDK will pick it up. In at least one embodiment, asynchronous communication through a queue may be useful as it may allow any instance of an application to pick up work as it becomes available. Results may be transferred back through a queue, to ensure no data is lost. In at least one embodiment, queues may also provide an ability to segment work, as highest priority work may go to a queue with most instances of an application connected to it, while lowest priority work may go to a queue with a single instance connected to it that processes tasks in an order received. In at least one embodiment, an application may run on a GPU-accelerated instance generated in cloud 1426, and an inference service may perform inferencing on a GPU.

In at least one embodiment, visualization service(s) 1420 may be leveraged to generate visualizations for viewing outputs of applications and/or deployment pipeline(s) 1410. In at least one embodiment, GPUs/Graphics 1422 may be leveraged by visualization service(s) 1420 to generate visualizations. In at least one embodiment, rendering effects, such as ray-tracing, may be implemented by visualization service(s) 1420 to generate higher quality visualizations. In at least one embodiment, visualizations may include, without limitation, 2D image renderings, 3D volume renderings, 3D volume reconstruction, 2D tomographic slices, virtual reality displays, augmented reality displays, etc. In at least one embodiment, virtualized environments may be used to generate a virtual interactive display or environment (e.g., a virtual environment) for interaction by users of a system (e.g., doctors, nurses, radiologists, etc.). In at least one embodiment, visualization service(s) 1420 may include an internal visualizer, cinematics, and/or other rendering or image processing capabilities or functionality (e.g., ray tracing, rasterization, internal optics, etc.).

In at least one embodiment, hardware 1322 may include GPUs/Graphics 1422, AI system 1424, cloud 1426, and/or any other hardware used for executing training system 1304 and/or deployment system 1306. In at least one embodiment, GPUs/Graphics 1422 (e.g., NVIDIA's TESLA and/or QUADRO GPUs) may include any number of GPUs that may be used for executing processing tasks of compute service(s) 1416, AI service(s) 1418, visualization service(s) 1420, other services, and/or any of features or functionality of software 1318. For example, with respect to AI service(s) 1418, GPUs/Graphics 1422 may be used to perform pre-processing on imaging data (or other data types used by machine learning models), post-processing on outputs of machine learning models, and/or to perform inferencing (e.g., to execute machine learning models). In at least one embodiment, cloud 1426, AI system 1424, and/or other components of system 1400 may use GPUs/Graphics 1422. In at least one embodiment, cloud 1426 may include a GPU-optimized platform for deep learning tasks. In at least one embodiment, AI system 1424 may use GPUs, and cloud 1426- or at least a portion tasked with deep learning or inferencing-may be executed using one or more AI systems 1424. As such, although hardware 1322 is illustrated as discrete components, this is not intended to be limiting, and any components of hardware 1322 may be combined with, or leveraged by, any other components of hardware 1322.

In at least one embodiment, AI system 1424 may include a purpose-built computing system (e.g., a super-computer or an HPC) configured for inferencing, deep learning, machine learning, and/or other artificial intelligence tasks. In at least one embodiment, AI system 1424 (e.g., NVIDIA's DGX) may include GPU-optimized software (e.g., a software stack) that may be executed using a plurality of GPUs/Graphics 1422, in addition to CPUs, RAM, storage, and/or other components, features, or functionality. In at least one embodiment, one or more AI systems 1424 may be implemented in cloud 1426 (e.g., in a data center) for performing some or all of AI-based processing tasks of system 1400.

In at least one embodiment, cloud 1426 may include a GPU-accelerated infrastructure (e.g., NVIDIA's NGC) that may provide a GPU-optimized platform for executing processing tasks of system 1400. In at least one embodiment, cloud 1426 may include an AI system 1424 for performing one or more of AI-based tasks of system 1400 (e.g., as a hardware abstraction and scaling platform). In at least one embodiment, cloud 1426 may integrate with application orchestration system 1428 leveraging multiple GPUs to enable seamless scaling and load balancing between and among applications and services 1320. In at least one embodiment, cloud 1426 may tasked with executing at least some of services 1320 of system 1400, including compute service(s) 1416, AI service(s) 1418, and/or visualization service(s) 1420, as described herein. In at least one embodiment, cloud 1426 may perform small and large batch inference (e.g., executing NVIDIA's TENSOR RT), provide an accelerated parallel computing API and platform 1430 (e.g., NVIDIA's CUDA), execute application orchestration system 1428 (e.g., KUBERNETES), provide a graphics rendering API and platform (e.g., for ray-tracing, 2D graphics, 3D graphics, and/or other rendering techniques to produce higher quality cinematics), and/or may provide other functionality for system 1400.

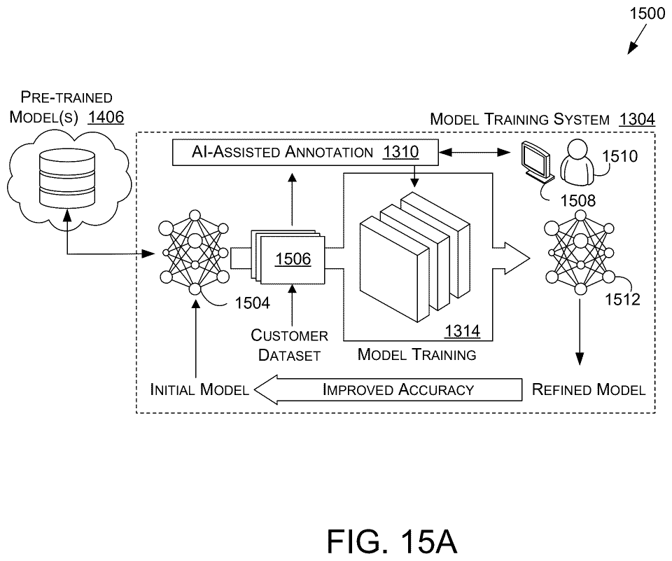

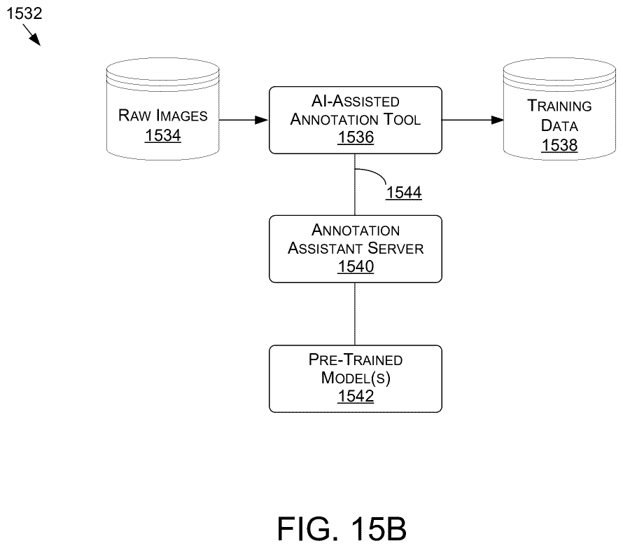

FIG. 15A illustrates a data flow diagram for a process 1500 to train, retrain, or update a machine learning model, in accordance with at least one embodiment. In at least one embodiment, process 1500 may be executed using, as a non-limiting example, system 1400 of FIG. 14. In at least one embodiment, process 1500 may leverage services and/or hardware as described herein. In at least one embodiment, refined models 1512 generated by process 1500 may be executed by a deployment system for one or more containerized applications in deployment pipelines.

In at least one embodiment, model training 1514 may include retraining or updating an initial model 1504 (e.g., a pre-trained model) using new training data (e.g., new input data, such as customer dataset 1506, and/or new ground truth data associated with input data). In at least one embodiment, to retrain, or update, initial model 1504, output or loss layer(s) of initial model 1504 may be reset, deleted, and/or replaced with an updated or new output or loss layer(s). In at least one embodiment, initial model 1504 may have previously fine-tuned parameters (e.g., weights and/or biases) that remain from prior training, so training or retraining 1514 may not take as long or require as much processing as training a model from scratch. In at least one embodiment, during model training 1514, by having reset or replaced output or loss layer(s) of initial model 1504, parameters may be updated and re-tuned for a new dataset based on loss calculations associated with accuracy of output or loss layer(s) at generating predictions on new, customer dataset 1506.

In at least one embodiment, pre-trained models 1506 may be stored in a data store, or registry. In at least one embodiment, pre-trained models 1506 may have been trained, at least in part, at one or more facilities other than a facility executing process 1500. In at least one embodiment, to protect privacy and rights of patients, subjects, or clients of different facilities, pre-trained models 1506 may have been trained, on-premise, using customer or patient data generated on-premise. In at least one embodiment, pre-trained models 1506 may be trained using a cloud and/or other hardware, but confidential, privacy protected patient data may not be transferred to, used by, or accessible to any components of a cloud (or other off premise hardware). In at least one embodiment, where pre-trained models 1506 is trained at using patient data from more than one facility, pre-trained models 1506 may have been individually trained for each facility prior to being trained on patient or customer data from another facility. In at least one embodiment, such as where a customer or patient data has been released of privacy concerns (e.g., by waiver, for experimental use, etc.), or where a customer or patient data is included in a public dataset, a customer or patient data from any number of facilities may be used to train pre-trained models 1506 on-premise and/or off premise, such as in a datacenter or other cloud computing infrastructure.

In at least one embodiment, when selecting applications for use in deployment pipelines, a user may also select machine learning models to be used for specific applications. In at least one embodiment, a user may not have a model for use, so a user may select a pre-trained model to use with an application. In at least one embodiment, pre-trained model may not be optimized for generating accurate results on customer dataset 1506 of a facility of a user (e.g., based on patient diversity, demographics, types of medical imaging devices used, etc.). In at least one embodiment, prior to deploying a pre-trained model into a deployment pipeline for use with an application(s), pre-trained model may be updated, retrained, and/or fine-tuned for use at a respective facility.

In at least one embodiment, a user may select pre-trained model that is to be updated, retrained, and/or fine-tuned, and this pre-trained model may be referred to as initial model 1504 for a training system within process 1500. In at least one embodiment, a customer dataset 1506 (e.g., imaging data, genomics data, sequencing data, or other data types generated by devices at a facility) may be used to perform model training (which may include, without limitation, transfer learning) on initial model 1504 to generate refined model 1512. In at least one embodiment, ground truth data corresponding to customer dataset 1506 may be generated by training system 1304. In at least one embodiment, ground truth data may be generated, at least in part, by clinicians, scientists, doctors, practitioners, at a facility.

In at least one embodiment, AI-assisted annotation may be used in some examples to generate ground truth data. In at least one embodiment, AI-assisted annotation (e.g., implemented using an AI-assisted annotation SDK) may leverage machine learning models (e.g., neural networks) to generate suggested or predicted ground truth data for a customer dataset. In at least one embodiment, a user may use annotation tools within a user interface (a graphical user interface (GUI)) on a computing device.

In at least one embodiment, user 1510 may interact with a GUI via computing device 1508 to edit or fine-tune (auto)annotations. In at least one embodiment, a polygon editing feature may be used to move vertices of a polygon to more accurate or fine-tuned locations.

In at least one embodiment, once customer dataset 1506 has associated ground truth data, ground truth data (e.g., from AI-assisted annotation, manual labeling, etc.) may be used by during model training to generate refined model 1512. In at least one embodiment, customer dataset 1506 may be applied to initial model 1504 any number of times, and ground truth data may be used to update parameters of initial model 1504 until an acceptable level of accuracy is attained for refined model 1512. In at least one embodiment, once refined model 1512 is generated, refined model 1512 may be deployed within one or more deployment pipelines at a facility for performing one or more processing tasks with respect to medical imaging data.

In at least one embodiment, refined model 1512 may be uploaded to pre-trained models in a model registry to be selected by another facility. In at least one embodiment, this process may be completed at any number of facilities such that refined model 1512 may be further refined on new datasets any number of times to generate a more universal model.

FIG. 15B is an example illustration of a client-server architecture 1532 to enhance annotation tools with pre-trained annotation models, in accordance with at least one embodiment. In at least one embodiment, AI-assisted annotation tool 1536 may be instantiated based on a client-server architecture 1532. In at least one embodiment, AI-assisted annotation tool 1536 in imaging applications may aid radiologists, for example, identify organs and abnormalities. In at least one embodiment, imaging applications may include software tools that help user 1510 to identify, as a non-limiting example, a few extreme points on a particular organ of interest in raw images 1534 (e.g., in a 3D MRI or CT scan) and receive auto-annotated results for all 2D slices of a particular organ. In at least one embodiment, results may be stored in a data store as training data 1538 and used as (for example and without limitation) ground truth data for training. In at least one embodiment, when computing device 1508 sends extreme points for AI-assisted annotation, a deep learning model, for example, may receive this data as input and return inference results of a segmented organ or abnormality. In at least one embodiment, pre-instantiated annotation tools, such as AI-assisted annotation tool 1536 in FIG. 15B, may be enhanced by making API calls (e.g., API Call 1544) to a server, such as an Annotation Assistant Server 1540 that may include a set of pre-trained models 1542 stored in an annotation model registry, for example. In at least one embodiment, an annotation model registry may store pre-trained models 1542 (e.g., machine learning models, such as deep learning models) that are pre-trained to perform AI-assisted annotation on a particular organ or abnormality. These models may be further updated by using training pipelines. In at least one embodiment, pre-installed annotation tools may be improved over time as new labeled data is added.

Such components can allow for optimizing camera placements for improved user experience.

The following clauses can describe various embodiments:
1. A computer-implemented method comprising:
   generating a spatial representation of an environment that defines accessible and inaccessible regions of the environment;
   determining connectivity information for a set of locations within spatial representation by analyzing one or more sightlines within the accessible regions in at least one direction;
   identifying one or more focus points within the spatial representation based at least on the connectivity information;
   selecting one or more camera placement locations for at least one of the one or more identified focus points based at least on a set of placement constraints;
   positioning a camera at a selected camera placement location based at least on an amount of visibility coverage of the environment at the location; and
   updating the spatial representation based at least on a visibility coverage of the positioned camera.
2. The computer-implemented method of clause 1, wherein the selecting one or more camera placement locations comprises:
   performing a ray casting operation from at least one identified focus point to detect potential obstructions along multiple sightlines;
   filtering potential camera placement locations by excluding camera placement locations where a ray intersects an obstruction; and
   selecting a camera placement location based at least on the filtering and a predefined ranking criterion.
3. The computer-implemented method of clause 1, wherein updating the spatial representation based at least on a coverage of the camera comprises:
   modifying one or more connectivity values within the spatial representation by reducing one or more connectivity scores for camera placement locations inside a field of view of the camera;
   marking one or more covered areas as inactive for further camera placement evaluation; and
   recalculating one or more focus points based on the one or more modified connectivity values before placing one or more additional cameras.
4. The computer-implemented method of clause 1, wherein positioning a camera at a selected camera placement location comprises:
   calculating an optimal orientation for the camera based on the selected camera placement location and the focus point, wherein the camera is oriented to maximize a visibility coverage of the focus point.
5. The computer-implemented method of clause 1, wherein the camera placement locations are evaluated based on criteria including at least one of: connectivity values, proximity to scene boundaries, or optimal viewing angles.
6. The computer-implemented method of clause 1, wherein the connectivity information comprises one or more connectivity values assigned to each of at least one location within the spatial representation, wherein each of the one or more connectivity values represents a measure of accessibility in one or more directions.
7. The computer-implemented method of clause 1, wherein selecting one or more camera placement locations includes categorizing placements into directional groups based on one or more predefined yaw rotation ranges and selecting a placement that maximizes coverage while minimizing redundancy.
8. The computer-implemented method of clause 2, wherein performing a ray casting operation includes restricting potential camera placement locations based on a predefined distance range and field-of-view constraints while eliminating camera placement locations with excessive obstructions.
9. At least one processor comprising:
   one or more processing units to:
   generate a spatial representation of an environment that defines accessible and inaccessible regions;
   determine connectivity information for a set of locations within the spatial representation by analyzing one or more sightlines within the accessible regions in at least one direction;
   identify one or more focus points within the spatial representation based at least on the connectivity information;
   select one or more camera placement locations for at least one of the one or more identified focus points based at least on a set of placement constraints; and
   position a camera at a selected camera placement location based on an amount of visibility coverage within the environment.
10. The processor of clause 9, wherein the one or more processing units are further to:
   perform a ray casting operation from at least one identified focus point to detect potential obstructions along multiple sightlines;
   filter potential camera placement locations by excluding camera placement locations where a ray intersects an obstruction; and
   select the camera placement location based at least on the filtering and a ranking criterion.
11. The processor of clause 9, wherein the one or more processing units are further to:
   modify one or more connectivity values within the spatial representation by reducing one or more connectivity scores for camera placement locations inside a field of view of the camera;
   mark one or more covered areas as inactive for further camera placement evaluation; and
   recalculate one or more focus points based on the one or more modified connectivity values before placing one or more additional cameras.
12. The processor of clause 9, wherein the one or more processing units are further to:
   calculate an optimal orientation for the camera based on the selected camera placement location and the focus point, wherein the camera is oriented to maximize visibility coverage of the focus point.
13. The processor of clause 9, wherein the camera placement locations are ranked based on criteria including at least one of: connectivity values, proximity to scene boundaries, or optimal viewing angles.
14. The processor of clause 9, wherein the connectivity information comprises one or more connectivity values assigned to each of at least one location within the spatial representation, wherein each of the one or more connectivity values represents a measure of accessibility in one or more directions.
15. The processor of clause 9, wherein the processor is included in a system comprising at least one of:
   a system for performing simulation operations;
   a system for performing simulation operations to test or validate autonomous machine applications;
   a system for performing digital twin operations;
   a system for performing light transport simulation;
   a system for rendering graphical output;
   a system for performing deep learning operations;
   a system implemented using an edge device;
   a system for generating or presenting virtual reality (VR) content;
   a system for generating or presenting augmented reality (AR) content;
   a system for generating or presenting mixed reality (MR) content;
   a system incorporating one or more Virtual Machines (VMs);
   a system implemented at least partially in a data center;
   a system for performing hardware testing using simulation;
   a system for synthetic data generation;
   a system for performing generative AI operations;
   a system implemented using one or more large language model (LLMs);
   a system implemented using one or more vision language model (VLMs);
   a system implemented using one or more multi-modal language model (MMLMs);
   a system using or deploying one or more inference microservices;
   a system that incorporates one or more machine learning models deployed in a service or microservice along with an OS-level virtualization package;
   a collaborative content creation platform for 3D assets; or
   a system implemented at least partially using cloud computing resources.
16. A system, comprising:
   one or more processing units to position, using a spatial representation of an environment that defines accessible and inaccessible regions of an environment, a camera at a selected camera placement location that provides at least a threshold of visibility coverage within the environment, one or more focus points being identified within the spatial representation by analyzing visibility for the accessible regions, wherein one or more camera placement locations for at least one of the one or more identified focus points are determined based on a set of constraints, and wherein the spatial representation is updated based at least on a coverage of the camera.
17. The system of clause 16, wherein the one or more processing units are further to:
   perform a ray casting operation from at least one identified focus point to detect potential obstructions along one or more sightlines;
   filter potential camera placement locations by excluding camera placement locations where a ray intersects an obstruction; and
   select a camera placement location based at least on the filtering and a criterion.
18. The system of clause 16, wherein the one or more processing units are further to:
   modify one or more connectivity values within the spatial representation by reducing one or more connectivity scores for camera placement locations inside a field of view of the camera;
   mark one or more covered areas as inactive for further camera placement evaluation; and
   recalculate one or more focus points based on the one or more modified connectivity values before placing one or more additional cameras.
19. The system of clause 16, wherein the one or more processing units are further to:
   calculate an optimal orientation for the camera based on the selected camera placement location and the focus point, wherein the camera is oriented to maximize coverage of the focus point.
20. The system of clause 16, wherein the camera placement locations are evaluated based on criteria including at least one of: connectivity values, proximity to scene boundaries, or optimal viewing angles.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors —for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or example language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

All references, including publications, patent applications, and patents, cited herein are hereby incorporated by reference to same extent as if each reference were individually and specifically indicated to be incorporated by reference and were set forth in its entirety herein.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as example forms of implementing the claims.

What is claimed is:

1. A computer-implemented method comprising:
generating a spatial representation of an environment that defines accessible and inaccessible regions of the environment;
determining connectivity information for a set of locations within spatial representation by analyzing one or more sightlines within the accessible regions in at least one direction;
identifying one or more focus points within the spatial representation based at least on the connectivity information;
selecting one or more camera placement locations for at least one of the one or more identified focus points based at least on a set of placement constraints;
positioning a camera at a selected camera placement location based at least on an amount of visibility coverage of the environment at the location; and
updating the spatial representation based at least on a visibility coverage of the positioned camera.

2. The computer-implemented method of claim 1, wherein the selecting one or more camera placement locations comprises:
performing a ray casting operation from at least one identified focus point to detect potential obstructions along multiple sightlines;
filtering potential camera placement locations by excluding camera placement locations where a ray intersects an obstruction; and
selecting a camera placement location based at least on the filtering and a predefined ranking criterion.

3. The computer-implemented method of claim 1, wherein updating the spatial representation based at least on a coverage of the camera comprises:
modifying one or more connectivity values within the spatial representation by reducing one or more connectivity scores for camera placement locations inside a field of view of the camera;
marking one or more covered areas as inactive for further camera placement evaluation; and
recalculating one or more focus points based on the one or more modified connectivity values before placing one or more additional cameras.

4. The computer-implemented method of claim 1, wherein positioning a camera at a selected camera placement location comprises:
calculating an optimal orientation for the camera based on the selected camera placement location and the focus point, wherein the camera is oriented to maximize a visibility coverage of the focus point.

5. The computer-implemented method of claim 1, wherein the camera placement locations are evaluated based on criteria including at least one of: connectivity values, proximity to scene boundaries, or optimal viewing angles.

6. The computer-implemented method of claim 1, wherein the connectivity information comprises one or more connectivity values assigned to each of at least one location within the spatial representation, wherein each of the one or more connectivity values represents a measure of accessibility in one or more directions.

7. The computer-implemented method of claim 1, wherein selecting one or more camera placement locations includes categorizing placements into directional groups based on one or more predefined yaw rotation ranges and selecting a placement that maximizes coverage while minimizing redundancy.

8. The computer-implemented method of claim 2, wherein performing a ray casting operation includes restricting potential camera placement locations based on a predefined distance range and field-of-view constraints while eliminating camera placement locations with excessive obstructions.

9. At least one processor comprising:
one or more processing units to:
generate a spatial representation of an environment that defines accessible and inaccessible regions;
determine connectivity information for a set of locations within the spatial representation by analyzing one or more sightlines within the accessible regions in at least one direction;
identify one or more focus points within the spatial representation based at least on the connectivity information;
select one or more camera placement locations for at least one of the one or more identified focus points based at least on a set of placement constraints; and
position a camera at a selected camera placement location based on an amount of visibility coverage within the environment.

10. The processor of claim 9, wherein the one or more processing units are further to:
perform a ray casting operation from at least one identified focus point to detect potential obstructions along multiple sightlines;
filter potential camera placement locations by excluding camera placement locations where a ray intersects an obstruction; and
select the camera placement location based at least on the filtering and a ranking criterion.

11. The processor of claim 9, wherein the one or more processing units are further to:
modify one or more connectivity values within the spatial representation by reducing one or more connectivity scores for camera placement locations inside a field of view of the camera;
mark one or more covered areas as inactive for further camera placement evaluation; and
recalculate one or more focus points based on the one or more modified connectivity values before placing one or more additional cameras.

12. The processor of claim 9, wherein the one or more processing units are further to:
calculate an optimal orientation for the camera based on the selected camera placement location and the focus point, wherein the camera is oriented to maximize visibility coverage of the focus point.

13. The processor of claim 9, wherein the camera placement locations are ranked based on criteria including at least one of: connectivity values, proximity to scene boundaries, or optimal viewing angles.

14. The processor of claim 9, wherein the connectivity information comprises one or more connectivity values assigned to each of at least one location within the spatial representation, wherein each of the one or more connectivity values represents a measure of accessibility in one or more directions.

15. The processor of claim 9, wherein the processor is included in a system comprising at least one of:
a system for performing simulation operations;
a system for performing simulation operations to test or validate autonomous machine applications;
a system for performing digital twin operations;
a system for performing light transport simulation;
a system for rendering graphical output;
a system for performing deep learning operations;
a system implemented using an edge device;
a system for generating or presenting virtual reality (VR) content;
a system for generating or presenting augmented reality (AR) content;
a system for generating or presenting mixed reality (MR) content;
a system incorporating one or more Virtual Machines (VMs);
a system implemented at least partially in a data center;
a system for performing hardware testing using simulation;
a system for synthetic data generation;
a system for performing generative AI operations;
a system implemented using one or more large language model (LLMs);
a system implemented using one or more vision language model (VLMs);
a system implemented using one or more multi-modal language model (MMLMs);
a system using or deploying one or more inference microservices;
a system that incorporates one or more machine learning models deployed in a service or microservice along with an OS-level virtualization package;
a collaborative content creation platform for 3D assets; or
a system implemented at least partially using cloud computing resources.

16. A system, comprising:
one or more processing units to position, using a spatial representation of an environment that defines accessible and inaccessible regions of an environment, a camera at a selected camera placement location that provides at least a threshold of visibility coverage within the environment, one or more focus points being identified within the spatial representation by analyzing visibility for the accessible regions, wherein one or more camera placement locations for at least one of the one or more identified focus points are determined based on a set of constraints, and wherein the spatial representation is updated based at least on a coverage of the camera.

17. The system of claim 16, wherein the one or more processing units are further to:
perform a ray casting operation from at least one identified focus point to detect potential obstructions along one or more sightlines;
filter potential camera placement locations by excluding camera placement locations where a ray intersects an obstruction; and
select a camera placement location based at least on the filtering and a criterion.

18. The system of claim 16, wherein the one or more processing units are further to:
modify one or more connectivity values within the spatial representation by reducing one or more connectivity scores for camera placement locations inside a field of view of the camera;
mark one or more covered areas as inactive for further camera placement evaluation; and
recalculate one or more focus points based on the one or more modified connectivity values before placing one or more additional cameras.

19. The system of claim 16, wherein the one or more processing units are further to:
calculate an optimal orientation for the camera based on the selected camera placement location and the focus point, wherein the camera is oriented to maximize coverage of the focus point.

20. The system of claim 16, wherein the camera placement locations are evaluated based on criteria including at least one of: connectivity values, proximity to scene boundaries, or optimal viewing angles.
